(19) United States
(12) Patent Application Publication
(10) Pub. No.: US 2025/0155483 A1
(43) Pub. Date: May 15, 2025

(54) SEMICONDUCTOR MEASUREMENT DEVICE AND SEMICONDUCTOR MEASUREMENT METHOD

(71) Applicant: Renesas Electronics Corporation, Tokyo (JP)

(72) Inventor: Takehiro UEDA, Tokyo (JP)

(21) Appl. No.: 18/944,669

(22) Filed: Nov. 12, 2024

(30) Foreign Application Priority Data
Nov. 13, 2023 (JP) 2023-192776

(51) Int. Cl. G01R 27/26; G01R 31/26

(52) U.S. Cl. CPC G01R 27/2605; G01R 31/2608; G01R 31/2621

(57) ABSTRACT

According to an embodiment, a semiconductor measurement device includes a CBCM circuit having a first terminal and a connection terminal and a potential difference application circuit connected to the connection terminal, the potential difference application circuit having a second terminal and applying a predetermined potential difference with respect to an output of the first terminal. The semiconductor measurement device obtains the parasitic capacitance of a measurement system from a capacitance in a connected state in which the first terminal and the second terminal are connected to a transistor and a capacitance in a disconnected state in which the first terminal and the second terminal are disconnected from the transistor, and calculates the capacitance of the transistor.

### CROSS-REFERENCE TO RELATED APPLICATIONS

The disclosure of Japanese Patent Application No. 2023-192776 filed on Nov. 13, 2023 including the specification, drawings and abstract is incorporated herein by reference in its entirety.

### BACKGROUND

The present disclosure relates to a semiconductor measurement device and a semiconductor measurement method, and for example, relates to a semiconductor measurement device and a semiconductor measurement method for a semiconductor device such as a metal-oxide-semiconductor field-effect transistor (MOSFET) and an insulated gate bipolar transistor (IGBT).

There are disclosed techniques listed below.
[Patent Document 1] Japanese Unexamined Patent Application Publication No. 2004-356169

Patent Document 1 describes a capacitance measurement circuit and a capacitance measurement method for a semiconductor device.

### SUMMARY

When the capacitance of the semiconductor device is measured, it is necessary to eliminate parasitic capacitance. In some members, however, it is difficult to eliminate the parasitic capacitance and thus it is difficult to improve the accuracy in measuring the capacitance of the semiconductor device.

Other problems and novel features would become apparent from the description of the present specification and the accompanying drawings.

According to an embodiment, a semiconductor measurement device includes: a CBCM circuit having a first terminal and an auxiliary terminal; and a potential difference application circuit connected to the auxiliary terminal, the potential difference application circuit having a second terminal and applying a predetermined potential difference with respect to an output of the first terminal, and the semiconductor measurement device obtains the parasitic capacitance of a measurement system from a capacitance in a connected state in which the first terminal and the second terminal are connected to a transistor and a capacitance in a disconnected state in which the first terminal and the second terminal are disconnected from the transistor, and calculates the capacitance of the transistor.

According to an embodiment, a semiconductor measurement method uses a semiconductor measurement device including: a CBCM circuit having a first terminal and an auxiliary terminal; and a potential difference application circuit connected to the auxiliary terminal, the potential difference application circuit having a second terminal and applying a predetermined potential difference with respect to an output of the first terminal, and the semiconductor measurement method includes: obtaining the parasitic capacitance of a measurement system from a capacitance in a connected state in which the first terminal and the second terminal are connected to a transistor and a capacitance in a disconnected state in which the first terminal and the second terminal are disconnected from the transistor, and calculating the capacitance of the transistor.

According to the above embodiment, it is possible to provide a semiconductor measurement device and a semiconductor measurement method capable of improving the accuracy in measuring the capacitance.

### BRIEF DESCRIPTION OF THE DRAWINGS

FIG. 1 is a circuit diagram illustrating a capacitance measurement circuit according to Comparative Example 1.

FIG. 2 is a diagram illustrating capacitance between a gate, a drain, and a source in a transistor to be measured in the capacitance measurement circuit according to Comparative Example 1.

FIG. 3 is a circuit diagram illustrating a capacitance measurement circuit according to Comparative Example 2.

FIG. 4 is a sequence diagram illustrating an operation of the capacitance measurement circuit according to Comparative Example 2, in which a horizontal axis indicates time, and a vertical axis indicates a voltage Vnode of a node N1, a current I (Vnode) of the node N1, a voltage of a gate circuit Ppgu, and a voltage of the gate circuit Npgu.

FIG. 5 is a circuit diagram illustrating an operation of the capacitance measurement circuit according to Comparative Example 2 during charging.

FIG. 6 is a circuit diagram illustrating an operation of the capacitance measurement circuit according to Comparative Example 2 during discharging.

FIG. 7 is a circuit diagram illustrating a main part of a semiconductor measurement device according to a first embodiment.

FIG. 8 is a circuit diagram illustrating the semiconductor measurement device according to the first embodiment.

FIG. 9 is a circuit diagram illustrating the semiconductor measurement device according to the first embodiment.

FIG. 10 is a diagram illustrating a semiconductor measurement method in the semiconductor measurement device according to the first embodiment.

FIG. 11 is a circuit diagram illustrating a semiconductor measurement device according to a second embodiment.

FIG. 12 is a circuit diagram illustrating the semiconductor measurement device according to the second embodiment.

FIG. 13 is a diagram illustrating a semiconductor measurement method in the semiconductor measurement device according to the second embodiment.

FIG. 14 is a circuit diagram illustrating a semiconductor measurement device according to a third embodiment.

FIG. 15 is a circuit diagram illustrating the semiconductor measurement device according to the third embodiment.

FIG. 16 is a diagram illustrating a semiconductor measurement method in the semiconductor measurement device according to the third embodiment.

FIG. 17 is a circuit diagram illustrating a semiconductor measurement device according to a fourth embodiment.

FIG. 18 is a circuit diagram illustrating the semiconductor measurement device according to the fourth embodiment.

FIG. 19 is a diagram illustrating a semiconductor measurement method in the semiconductor measurement device according to the fourth embodiment.

FIG. 20 is a flow chart diagram illustrating a semiconductor measurement method in the semiconductor measurement devices according to the first to fourth embodiments. and

FIG. 21 is a flow chart diagram illustrating a semiconductor measurement method in the semiconductor measurement devices according to the first to fourth embodiments.

### DETAILED DESCRIPTION

For clarity of description, the following description and drawings are omitted and simplified as appropriate. In the drawings, the same elements are denoted by the same reference numerals, and redundant description is omitted as necessary. In addition, reference numerals are appropriately omitted so as not to complicate the drawing. The connection includes electrical connection.

First, a capacitance measurement circuit and a capacitance measurement method according to a comparative example will be described in <Comparative example>. Thereafter, in <Problem newly found by inventor>, problems newly found by the inventor with respect to the capacitance measurement circuit and the capacitance measurement method of the comparative example will be described. Then, in <First embodiment> to <Fourth embodiment>, a semiconductor measurement device and a semiconductor measurement method according to each embodiment will be described.

Accordingly, the semiconductor measurement device and the semiconductor measurement method according to each embodiment will be made clearer. Note that the capacitance measurement circuit and the capacitance measurement method according to the comparative example, and the problems newly found by the inventor are also within the scope of the technical idea of the embodiment.

### Comparative Example 1

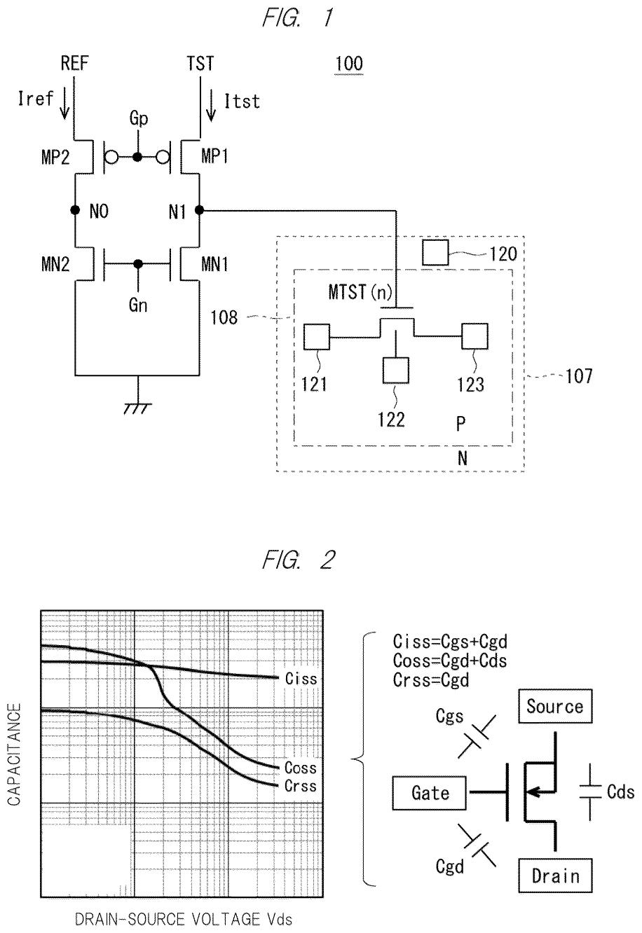

The capacitance measurement circuit and the capacitance measurement method according to Comparative Example 1 will be described. FIG. 1 is a circuit diagram illustrating a capacitance measurement circuit 100 according to Comparative Example 1. As illustrated in FIG. 1, the capacitance measurement circuit 100 according to Comparative Example 1 includes a PMOS transistor MP1, a PMOS transistor MP2, an NMOS transistor MN1, and an NMOS transistor MN2. The PMOS transistor MP2 and the NMOS transistor MN2 are directly connected. A reference potential REF is applied to a source of the PMOS transistor MP2. Thus, a current Iref flows through the source of the PMOS transistor MP2. A source of the NMOS transistor MN2 is grounded. A drain of the PMOS transistor MP2 and a drain of the NMOS transistor MN2 are connected at a node NO.

The PMOS transistor MP1 and the NMOS transistor MN1 are connected in series. A test potential TST is applied to a source of the PMOS transistor MP1. Thus, a current Itst flows through the source of the PMOS transistor MP1. A source of the NMOS transistor MN1 is grounded. A drain of the PMOS transistor MP1 and a drain of the NMOS transistor MN1 are connected at a node N1.

A PMOS gate potential Gp is applied to gates of the PMOS transistors MP1 and MP2, and an NMOS gate potential Gn is applied to gates of the NMOS transistors MN1 and MN2. The node N1 between the drain of the PMOS transistor MP1 and the drain of the NMOS transistor MN1 is connected to a gate electrode of an NMOS transistor MTST (n) to be measured formed in a P-well region 108 of a bottom N-well region 107. Note that the PMOS transistors MP1 and MP2 are formed with the same transistor size, and the NMOS transistors MN1 and MN2 are formed with the same transistor size.

In the NMOS transistor MTST (n) to be measured formed in the P-well region 108, a pad 121 is formed on the source region, a pad 122 is formed on the back gate region, a pad 123 is formed on the drain region, and a pad 120 is provided in the bottom N-well region 107. Due to the presence of the bottom N-well region 107, the NMOS transistors MN1 and MN2 for CBCM (Charge-Based Capacitance Measurement) and the NMOS transistor MTST (n) to be measured are separately formed.

By providing the pad 121 and the pad 123, it is possible to independently set a potential for the source region and the drain region of the NMOS transistor MTST (n) to be measured. Furthermore, by separating the NMOS transistors MN1 and MN2 from the NMOS transistor MTST (n) to be measured, it is possible to set the potential of the P-well region 108 (substrate potential (back gate potential)) using the pad 122. Therefore, in addition to the source region and the drain region of the NMOS transistor MTST (n) to be measured, the substrate potential can be set independently of the NMOS transistors MN1 and MN2. In addition, by fixing the bottom N-well region 107 at a potential at which a reverse bias is applied to the PN junction using the pad 120, it is possible to improve the separation characteristics between the NMOS transistors MN1 and MN2 for CBCM and the NMOS transistor MTST (n) to be measured.

By commonly connecting the pads 121 to 123 with an external cable and applying a fixed potential V1 to the external cable, a source-substrate junction capacitance Cjs and a drain-substrate junction capacitance Cjd can be set to “0”.

Therefore, the gate capacitance can be measured as a target capacitance by measuring a charge current (test current Itst) to the NMOS transistor MTST (n) to be measured by the CBCM method.

As described above, the general CBCM method has a circuit configuration in which a pair of the PMOS transistor MP1 and the NMOS transistor MN1 for charging and discharging the NMOS transistor MTST (n) to be measured and a pair of the PMOS transistor MP2 and the NMOS transistor MN2 for canceling the parasitic capacitance are connected to each other. The pair of the PMOS transistor MP2 and the NMOS transistor MN2 is not directly connected to the NMOS transistor MTST (n) to be measured.

FIG. 2 is a diagram illustrating the capacitance between the gate, the drain, and the source of the transistor of the measurement target MTST in the capacitance measurement circuit according to Comparative Example 1. As illustrated in FIG. 2, a capacitance Ciss, a capacitance Coss, and a capacitance Crss measured by changing a drain-source voltage Vds are defined as the following Formulas (1) to (3).

$$Ciss = Cgs + Cgd \qquad ( 1 )$$

$$Coss = Cgd + Cds \qquad ( 2 )$$

$$Crss = Cgd \qquad ( 3 )$$

Here, the capacitance Cgs represents a capacitance between the gate and the source, the capacitance Cgd represents a capacitance between the gate and the drain, and the capacitance Cds represents a capacitance between the drain and the source.

### Comparative Example 2

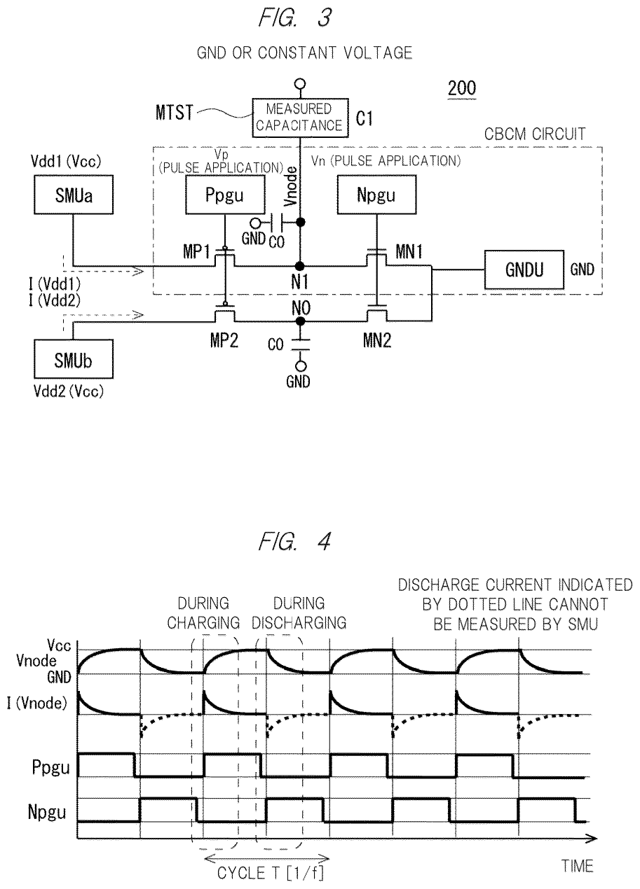

Next, the capacitance measurement circuit and the capacitance measurement method according to Comparative Example 2 will be described. FIG. 3 is a circuit diagram illustrating a capacitance measurement circuit 200 according to Comparative Example 2. As illustrated in FIG. 3, the capacitance measurement circuit 200 includes a PMOS transistor MP1, a PMOS transistor MP2, an NMOS transistor MN1, and an NMOS transistor MN2. The PMOS transistor MP1 and the NMOS transistor MN1 are directly connected. A measurement circuit SMUa is connected to a source of the PMOS transistor MP1. A ground circuit GNDU is connected to a source of the NMOS transistor MN1. A drain of the PMOS transistor MP1 and a drain of the NMOS transistor MN1 are connected at a node N1.

The PMOS transistor MP2 and the NMOS transistor MN2 are connected in series. A measurement circuit SMUb is connected to a source of the PMOS transistor MP2. The ground circuit GNDU is connected to a source of the NMOS transistor MN2. A drain of the PMOS transistor MP2 and a drain of the NMOS transistor MN2 are connected at a node NO.

A gate circuit Ppgu is connected to gates of the PMOS transistors MP1 and MP2. A gate circuit Npgu is connected to gates of the NMOS transistors MN1 and MN2. Note that, as in Comparative Example 1, the PMOS transistors MP1 and MP2 are formed with the same transistor size, and the NMOS transistors MN1 and MN2 are formed with the same transistor size.

The node N1 between the drain of the PMOS transistor MP1 and the drain of the NMOS transistor MN1 is connected to a measurement target MTST. One end of the measurement target MTST is connected to the node N1. The other end of the measurement target MTST is at a ground or a constant voltage. A capacitance C1 between the one end and the other end of the measurement target MTST is measured.

The gate circuit Ppgu applies a pulse voltage Vp that turns on or off the gates of the PMOS transistors MP1 and MP2. The gate circuit Npgu applies a pulse voltage Vn that turns on or off the gates of the NMOS transistors MN1 and MN2. The measurement circuit SMUa causes a current I (Vdd1) to flow by applying a voltage Vdd1 (Vcc). The measurement circuit SMUb causes a current I (Vdd2) to flow by applying a voltage Vdd2 (Vcc).

In the capacitance measurement circuit 200 of Comparative Example 2, the gate circuit Ppgu, the gate circuit Npgu, the PMOS transistor MP1, the NMOS transistor MN1, and the ground circuit GNDU constitute a CBCM circuit. That is, the CBCM circuit may include the gate circuit Ppgu, the gate circuit Npgu, the PMOS transistor MP1, the NMOS transistor MN1, and the ground circuit GNDU. With such a configuration, the capacitance measurement circuit 200 of Comparative Example 2 measures the measured capacitance C1 of the measurement target MTST. Note that the capacitance between the node N0 and the ground GND is a parasitic capacitance C0. The capacitance between the node N1 and the ground GND is the parasitic capacitance C0. A voltage Vnode is applied to the measurement target MTST via the node N1.

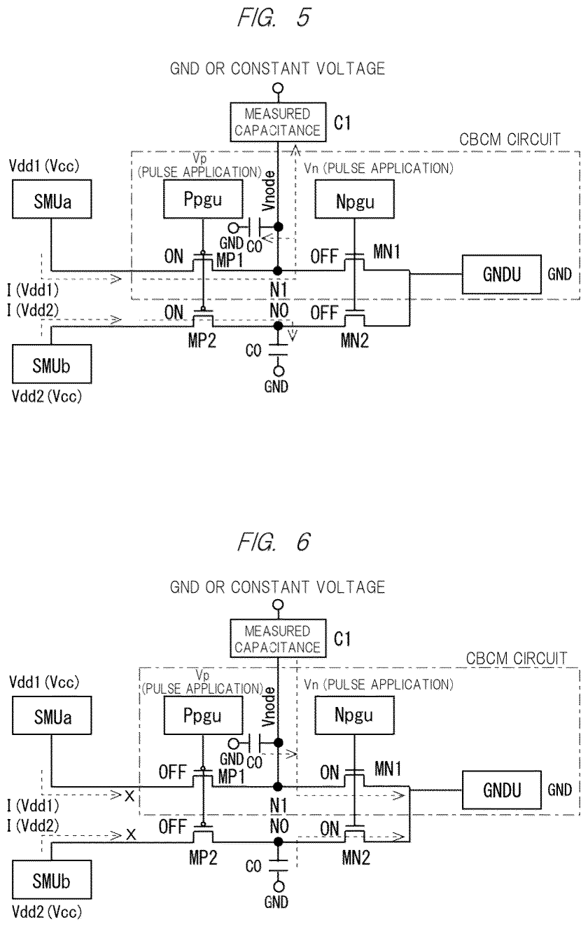

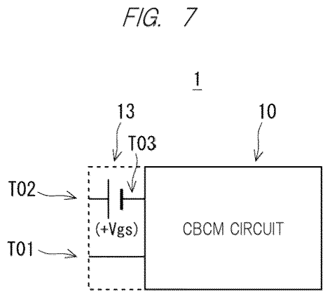

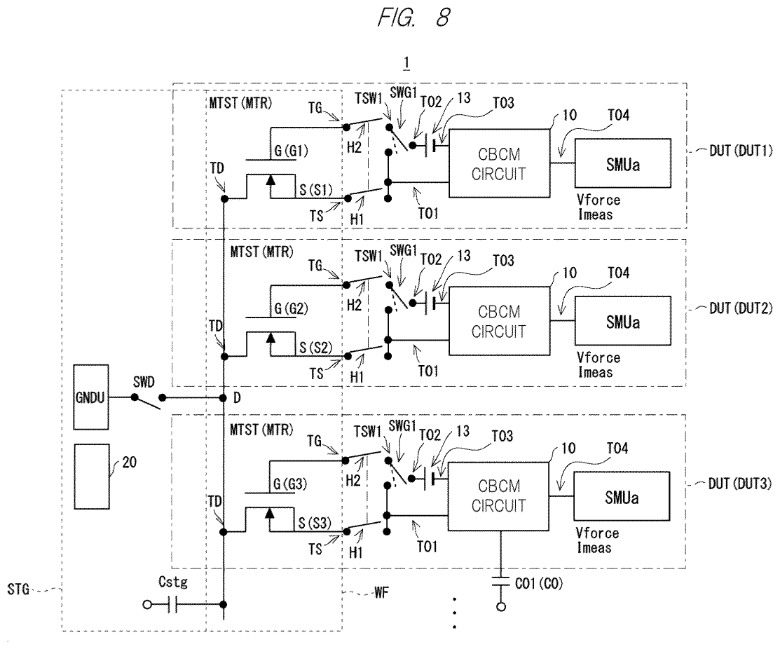

FIG. 4 is a sequence diagram illustrating an operation of the capacitance measurement circuit 200 according to Comparative Example 2, in which a horizontal axis indicates time, and a vertical axis indicates a voltage Vnode of a node N1, a current I (Vnode) of the node N1, a voltage of a gate circuit Ppgu, and a voltage of the gate circuit Npgu. FIG. 5 is a circuit diagram illustrating an operation of the capacitance measurement circuit 200 according to Comparative Example 2 during charging. FIG. 6 is a circuit diagram illustrating an operation of the capacitance measurement circuit 200 according to Comparative Example 2 during discharging.

As illustrated in FIGS. 4 and 5, when charging the measurement target MTST, the gate circuit Npgu applies a pulse voltage that turns off the gates of the NMOS transistors MN1 and MN2. Next, the gate circuit Ppgu applies a pulse voltage that turns on the gates of the PMOS transistors MP1 and MP2. Then, the current I (Vnode) flows through the node N1. As the current I (Vnode) flows through the node N1, the voltage Vnode at the node N1 gradually increases. Accordingly, the current I (Vnode) decreases. When the voltage Vnode at the node N1 is saturated, the current I (Vnode) becomes 0. In this manner, charges are accumulated in the measurement target MTST. The capacitance of the measurement target MTST is the capacitance C1. The parasitic capacitance C0 is also generated in this case.

As illustrated in FIGS. 4 and 6, when discharging the measurement target MTST, the gate circuit Ppgu applies a pulse voltage that turns off the gates of the PMOS transistors MP1 and MP2. Next, the gate circuit Npgu applies a pulse voltage that turns on the gates of the NMOS transistors MN1 and MN2. Then, the current I (Vnode) flows through the node N1. As indicated by a dotted line in the figure, the measurement circuit SMUa and the measurement circuit SMUb cannot measure the discharge current. As the current I (Vnode) during discharging flows through the node N1, the voltage Vnode at the node N1 decreases. Accordingly, the current I (Vnode) during discharging decreases. When the voltage Vnode at the node N1 becomes 0, the current I (Vnode) during discharging becomes 0. In this manner, charges are discharged from the measurement target MTST. One cycle of charging and discharging is a cycle T [1/f].

The capacitance C1 of the measurement target MTST is calculated by the following Formulas (4) and (5). Here, C0 is parasitic capacitance.

$$C 1 = ( C 1 + C 0 ) - C 0 \qquad ( 4 )$$

$$= ( I ( Vdd 1 ) - I ( Vdd 2 ) ) / ( Vcc \times f ) \qquad ( 5 )$$

Here, the relationship between the units in the above formula is expressed by the following Formula (6).

$$[ F ] = [ A ] / ( [ V ] \times [ Hz ] ) \qquad ( 6 )$$

### Problem Newly Found by Inventor

Next, the problems newly found by the inventor will be described. In the capacitance measurement circuit of Comparative Example 1, the measurement target MTST and the transistor pair for charging and discharging the measurement target MTST are arranged on the same wafer. The capacitance measurement circuit of Comparative Example 1 measures the capacitance C1 of the measurement target MTST with such a circuit configuration on the same wafer. However, for example, in a case where only the measurement target MTST is on the wafer and a transistor pair for charging and discharging the measurement target MTST is outside the wafer as in a capacitance measurement of a power MOS transistor, it is difficult to duplicate all the configurations including a probe needle.

In addition, for example, it is conceivable to switch capacitance measurement/parasitic capacitance measurement by raising/lowering a probe needle. However, in that case, it is difficult to measure the parasitic capacitance on a wafer stage side. Thus, the parasitic capacitance on the wafer stage side cannot be canceled. Furthermore, it is conceivable to install the CBCM circuit on the wafer stage side and arrange the measurement circuit on the opposite side across the measurement target to ignore the parasitic capacitance of the wafer stage. However, in that case, it is difficult to measure the parasitic capacitance from the measurement circuit to the probe needle, and the parasitic capacitance from the measurement circuit to the probe needle cannot be canceled.

### First Embodiment

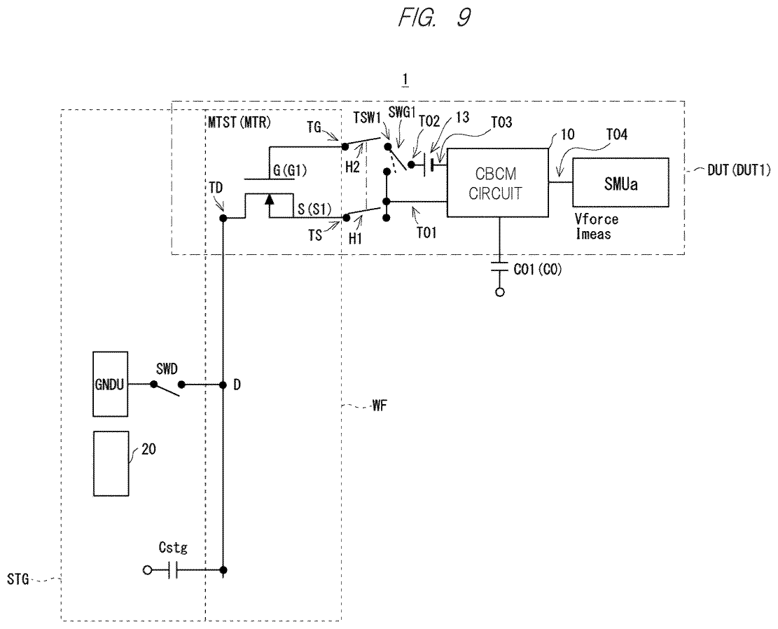

Next, a semiconductor measurement device and a semiconductor measurement method according to a first embodiment will be described. FIG. 7 is a circuit diagram illustrating a main part of a semiconductor measurement device 1 according to the first embodiment. As illustrated in FIG. 7, the semiconductor measurement device 1 includes a CBCM circuit 10 and a potential difference application circuit 13. The CBCM circuit 10 has a first terminal T01 and a connection terminal T03. The potential difference application circuit 13 is connected to the connection terminal T03. In addition, the potential difference application circuit 13 has a second terminal T02. The potential difference application circuit 13 outputs a predetermined potential difference with respect to an output of the first terminal T01 to the second terminal T02.

The semiconductor measurement device 1 measures a capacitance Coss and the like of a measurement target MTST. For example, the semiconductor measurement device 1 measures a capacitance in a connected state in which the first terminal T01 and the second terminal T02 are connected to the measurement target MTST, and a capacitance in a disconnected state in which the first terminal T01 and the second terminal T02 are disconnected from the measurement target MTST. With such a configuration, the semiconductor measurement device 1 obtains the parasitic capacitance of a measurement system from the capacitance in the connected state and the capacitance in the disconnected state, and calculates the capacitance Coss and the like of the measurement target MTST. The measurement system includes, for example, a stage.

As described above, the CBCM circuit 10 includes a charging transistor and a discharging transistor. The charging transistor outputs a predetermined charge voltage to the measurement target MTST via the first terminal T01 and the second terminal T02. The discharging transistor outputs a predetermined discharge voltage to the measurement target MTST via the first terminal T01 and the second terminal T02.

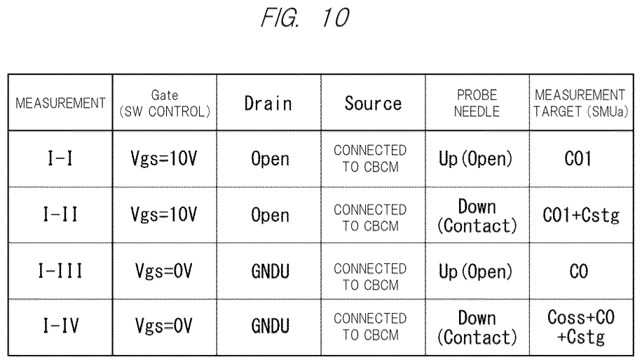

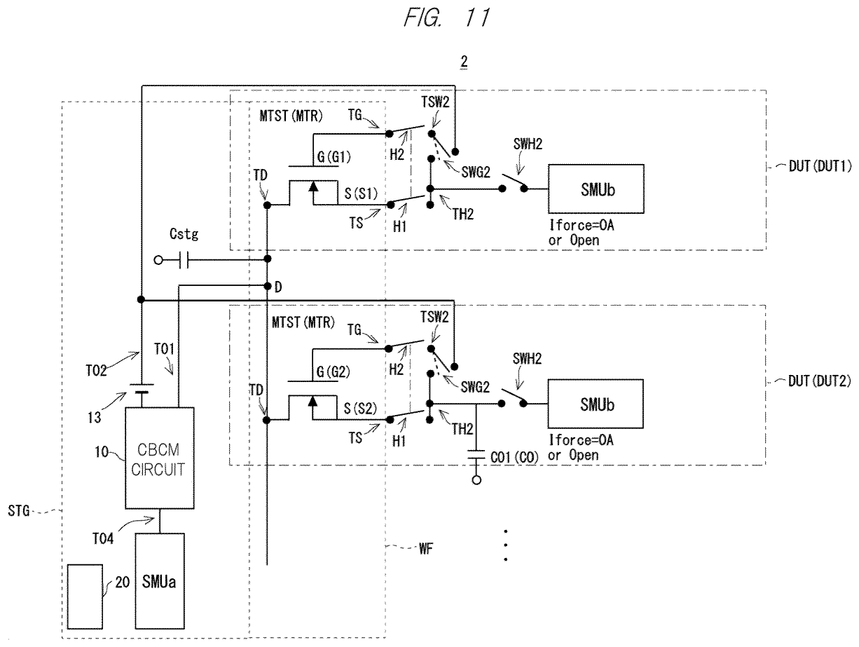

FIGS. 8 and 9 are circuit diagrams illustrating the semiconductor measurement device 1 according to the first embodiment. The semiconductor measurement device 1 of the present embodiment may measure each capacitance of a plurality of measurement targets MTST as illustrated in FIG. 8, or may measure the capacitance of one measurement target MTST as illustrated in FIG. 9.

The semiconductor measurement device 1 may include members arranged on a stage STG (a ground circuit GNDU and the like) and members separated from the stage STG (a probe card, the CBCM circuit 10, a measurement circuit SMUa, and the like). The measurement target MTST is formed on a wafer WF placed on the stage STG. In the semiconductor measurement device 1, the members separated from the stage STG and the measurement target MTST are collectively referred to as a measurement body DUT. In FIG. 9, the semiconductor measurement device 1 includes one measurement body DUT. In FIG. 8, the semiconductor measurement device 1 includes a plurality of measurement bodies DUT1 to DUT3 arranged in parallel. Note that the plurality of measurement bodies DUT are not limited to the three measurement bodies DUT1 to DUT3, and may include two measurement bodies DUT1 to DUT2, or may include four or more measurement bodies DUT. Hereinafter, for convenience of description, description will be made using FIG. 9.

The measurement target MTST includes a transistor MTR. The transistor MTR is formed on the wafer WF. The transistor MTR may include a gate G, a source S, and a drain D, or may include a base, an emitter, and a collector. Hereinafter, a transistor including the gate G, the source S, and the drain D will be described as the transistor MTR. In a case where the plurality of transistors MTR are measured, each transistor MTR includes gates G1, G2, or G3, sources S1, S2, or S3, and drains D1, D2, or D3.

The gate G is connected to a gate terminal TG. Thus, a terminal of the gate G is the gate terminal TG. The source S is connected to a source terminal TS. Thus, a terminal of the source S is the source terminal TS. The drain D is connected to a drain terminal TD. Thus, a terminal of the drain D is the drain terminal TG.

The source S or the emitter may be referred to as a first region, and the source terminal TS or the emitter terminal may be referred to as a first region terminal. In this case, the first region includes the source S or the emitter. The drain D or the collector may be referred to as a second region, and the drain terminal TD or the collector terminal may be referred to as a second region terminal. In this case, the second region includes the drain D or the collector. Note that the source S or the emitter may be replaced with the second region, or the source terminal TS or the emitter terminal may be replaced with the second region terminal. The drain D or the collector may be replaced with the first region, or the drain terminal TD or the collector terminal may be replaced with the first region terminal.

As illustrated in FIG. 9, the semiconductor measurement device 1 may include a measurement circuit SMUa, a switch terminal TSW1, a gate switch SWG1, a ground circuit GNDU, a drain switch SWD, probe needles H1 and H2, and a control unit 20 in addition to the CBCM circuit 10 and the potential difference application circuit 13. Note that the semiconductor measurement device 1 may further include members other than the above members, or some of the above members may be omitted. The drain switch SWD may be referred to as a second region switch. Note that the drain switch SWD may be replaced with a first region switch. The CBCM circuit 10 further has a measurement terminal T04.

The measurement circuit SMUa is connected to the measurement terminal T04 of the CBCM circuit 10. The measurement circuit SMUa applies a voltage Vforce to the CBCM circuit 10 and measures a current Imeas via the measurement terminal T04.

The probe needles H1 and H2 switch between the connected state in which the first terminal T01 and the second terminal T02 are connected to the transistor MTR and the disconnected state in which the first terminal T01 and the second terminal T02 are disconnected from the transistor MTR. The probe needle H1 and the probe needle H2 operate in conjunction with each other. The probe needle H1 connects the source terminal TS to the first terminal T01 in the connected state. The probe needle H2 connects the gate terminal TG to the switch terminal TSW1 in the connected state. On the other hand, the probe needle H1 disconnects the source terminal TS from the first terminal T01 in the disconnected state. The probe needle H2 disconnects the gate terminal TG from the switch terminal TSW1 in the disconnected state.

The switch terminal TSW1 is connected to the gate terminal TG in the connected state. The switch terminal TSW1 is disconnected from the gate terminal TG in the disconnected state. The first terminal T01 is connected to the source terminal TS in the connected state. The first terminal T01 is disconnected from the source terminal TS in the disconnected state.

The gate switch SWG1 has one end and the other end. The one end of the gate switch SWG1 is fixed to the switch terminal TSW1. The other end of the gate switch SWG1 is connected to the first terminal T01 or the second terminal T02. In this manner, the gate switch SWG1 connects the switch terminal TSW1 to the first terminal T01 or the second terminal T02.

The drain terminal TD is connected to the drain switch SWD. The drain switch SWD is connected to a ground circuit GNDU. The ground circuit GNDU outputs a ground potential. The drain switch SWD connects the drain terminal TD to the ground circuit GNDU and disconnects the drain terminal TD from the ground circuit GNDU.

The control unit 20 controls the operations of the gate switch SWG1, the drain switch SWD, the probe needles H1 and H2, and the measurement circuit SMUa. The control unit 20 may control the operation of the semiconductor measurement method described below.

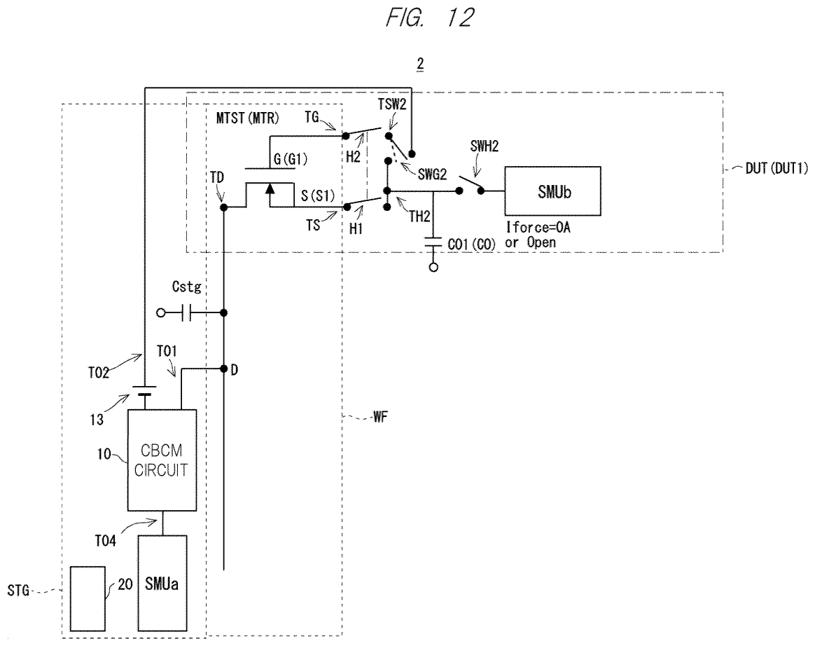

Next, the semiconductor measurement method for the measurement target MTST using the semiconductor measurement device 1 will be described. FIG. 10 is a diagram illustrating the semiconductor measurement method in the semiconductor measurement device 1 according to the first embodiment. As illustrated in FIG. 10, the semiconductor measurement method of the present embodiment includes a measurement I-I, a measurement I-II, a measurement I-III, and a measurement I-IV. Each measurement may be performed under the control of the control unit 20. Note that part or all of each measurement may be manually performed by a user of the semiconductor measurement device 1.

First, as illustrated in the measurement I-I in FIG. 10, the control unit 20 causes the gate switch SWG1 to connect the switch terminal TSW1 to the second terminal T02. Thus, when the probe needle H2 goes down, the gate terminal TG is connected to the switch terminal TSW1. As a result, an output of the second terminal T02 of the CBCM circuit 10 is applied to the gate G. For the output of the second terminal T02, a potential difference (for example, 10 V) with respect to the first terminal T01 is applied by the potential difference application circuit 13. As a result, when the probe needles H1 and H2 go down, a potential Vgs (for example, 10 V) is generated between the gate G and the source S.

In addition, the control unit 20 causes the drain switch SWD to be disconnected. Furthermore, when the probe needle H1 goes down, the source terminal TS is connected to the first terminal T01. As a result, the output of the first terminal T01 of the CBCM circuit 10 is applied to the source S.

With such a configuration, the control unit 20 causes the probe needle H1 to go up to bring the source terminal TS and the first terminal T01 into the disconnected state. In addition, the control unit 20 causes the probe needle H2 to go up to bring the gate terminal TG and the switch terminal TSW1 into the disconnected state. In this case, the control unit 20 causes the measurement circuit SMUa to measure a parasitic capacitance C01 of the plurality of measurement bodies DUT from the sum of currents flowing through the measurement terminals T04 of the respective measurement bodies DUT.

Next, as illustrated in the measurement I-II in FIG. 10, the control unit 20 causes the gate switch SWG1 to connect the switch terminal TSW1 to the second terminal T02. Thus, when the probe needle H2 goes down, the gate terminal TG is connected to the switch terminal TSW1. As a result, an output of the second terminal T02 of the CBCM circuit 10 is applied to the gate G.

In addition, the control unit 20 causes the drain switch SWD to be disconnected. Furthermore, when the probe needle H1 goes down, the source terminal TS is connected to the first terminal T01. As a result, the output of the first terminal T01 of the CBCM circuit 10 is applied to the source S.

With such a configuration, the control unit 20 causes the probe needle H1 to go down to bring the source terminal TS and the first terminal T01 into the connected state. In addition, the control unit 20 causes the probe needle H2 to go down to bring the gate terminal TG and the switch terminal TSW1 into the connected state. In this case, the control unit 20 causes the measurement circuit SMUa to measure the parasitic capacitance C01 of the plurality of measurement bodies DUT and a parasitic capacitance Cstg of the entire stage STG from the sum of currents flowing through the measurement terminals T04 of the respective measurement bodies DUT.

Next, as illustrated in the measurement I-III in FIG. 10, the control unit 20 causes the gate switch SWG1 to connect the switch terminal TSW1 to the first terminal T01. Thus, when the probe needle H2 goes down, the gate terminal TG is connected to the first terminal T01. As a result, the output of the first terminal T01 of the CBCM circuit 10 is applied to the gate G. Therefore, when the probe needles H1 and H2 go down, the potential Vgs between the gate G and the source S becomes 0 V.

In addition, the control unit 20 causes the drain switch SWD to be connected. Thus, the ground potential is applied to the drain D via the drain terminal TD. When the probe needle H1 goes down, the source terminal TS is connected to the first terminal T01. As a result, the output of the first terminal T01 of the CBCM circuit 10 is applied to the source S.

With such a configuration, the control unit 20 causes the probe needle H1 to go up to bring the source terminal TS and the first terminal T01 into the disconnected state. In addition, the control unit 20 causes the probe needle H2 to go up to bring the gate terminal TG and the switch terminal TSW1 into the disconnected state. In this case, the control unit 20 causes the measurement circuit SMUa to measure parasitic capacitances C0 of each measurement body DUT from the current flowing through each measurement terminal T04 of the respective measurement bodies DUT.

Next, as illustrated in the measurement I-IV in FIG. 10, the control unit 20 causes the gate switch SWG1 to connect the switch terminal TSW1 to the first terminal T01. Thus, when the probe needle H2 goes down, the gate terminal TG is connected to the first terminal T01. As a result, the output of the first terminal T01 of the CBCM circuit 10 is applied to the gate G.

In addition, the control unit 20 causes the drain switch SWD to be connected. Thus, the ground potential is applied to the drain D via the drain terminal TD. When the probe needle H1 goes down, the source terminal TS is connected to the first terminal T01. As a result, the output of the first terminal T01 of the CBCM circuit 10 is applied to the source S.

With such a configuration, the control unit 20 causes the probe needle H1 to go down to bring the source terminal TS and the first terminal T01 into the connected state. In addition, the control unit 20 causes the probe needle H2 to go down to bring the gate terminal TG and the switch terminal TSW1 into the connected state. In this case, the control unit 20 causes the measurement circuit SMUa to measure the capacitance Coss of the transistor MTR, the parasitic capacitance C0 of each measurement body DUT, and the parasitic capacitance Cstg of the stage STG of each measurement body DUT from the current flowing through each measurement terminal T04 of each measurement body DUT.

From the measurement I-I and the measurement I-II, the semiconductor measurement device 1 can calculate the parasitic capacitance Cstg of the entire stage STG. Here, a value obtained by dividing the parasitic capacitance Cstg of the entire stage STG by the number of the measurement bodies DUT in parallel can be approximately regarded as the parasitic capacitance Cstg of the stage STG of each measurement body DUT. In addition, the parasitic capacitance C0 of each measurement body DUT can be calculated from the measurement I-III. Then, from the parasitic capacitance Cstg and the parasitic capacitance C0 obtained from the measurement I-I, the measurement I-II, and the measurement I-III, and the measurement I-IV, the semiconductor measurement device 1 can calculate the capacitance Coss of the transistor MTR of each measurement body DUT. Specifically, the semiconductor measurement device 1 can calculate the capacitance Coss of the transistor MTR from: (Capacitance Coss of the transistor MTR of each measurement body DUT, parasitic capacitance C0 of each measurement body DUT, and parasitic capacitance Cstg of the stage STG)—(Parasitic capacitance C0 of each measurement body DUT)—(Parasitic capacitance Cstg of the entire stage STG/Number of the measurement bodies DUT in parallel).

Next, effects of the present embodiment will be described. The semiconductor measurement device 1 of the present embodiment includes the potential difference application circuit 13 that applies a potential difference relative to the output of the CBCM circuit 10. With this configuration, the semiconductor measurement device 1 can suppress the generation of charge and discharge of parasitic capacitances Cgd and Cgs of the transistor of the measurement target MTST by driving the gate G of the transistor of the measurement target MTST. Therefore, the accuracy in measuring the capacitance of the measurement target MTST can be improved. Thus, the semiconductor measurement device 1 according to the present embodiment can cancel the parasitic capacitance by providing an offset voltage operating in conjunction with the output of the CBCM circuit 10 and turning on the gate G of the device of the measurement target MTST as necessary.

In addition, in order to measure the parasitic capacitance C0 and the like, the semiconductor measurement device 1 turns on the transistor of the measurement target MTST (the drain-source path can be regarded as a simple resistance element.). Therefore, the target range of the charging and discharging of the CBCM method using the CBCM circuit 10 (parasitic capacitance measurement range) can be expanded.

Related semiconductor measurement methods include an auto balancing bridge method using an LCR meter. In the auto balancing bridge method, for example, only one device can be measured at a time during a wafer test, and parallel measurement is not possible. Thus, the auto balancing bridge method has a high load in terms of cost. In addition, capacitance measurement using a general CBCM circuit has a problem in a method of canceling the parasitic capacitance of a stage or the like when the capacitance measurement is parallelized during the wafer test, and thus it is difficult to parallelize the capacitance measurement.

On the other hand, the semiconductor measurement device 1 of the present embodiment can form a charging/discharging path to the stage by applying a potential difference to the gate G of the transistor (measurement target) on the wafer in conjunction with the output of the CBCM circuit 10. Thus, the parasitic capacitance Cstg of the stage can be canceled during the wafer test, and thus the capacitance measurement using the CBCM circuit 10 can be parallelized. In addition, since the potential of the gate G maintains a constant potential difference Vgs in synchronization with the first terminal of the CBCM circuit 10, charging and discharging of the parasitic capacitance Cgs and the parasitic capacitance Cgd of the transistor do not occur when the parasitic capacitance Cstg of the stage is measured, and thus, it is possible to improve the reliability of the measurement of the parasitic capacitance Cstg of the stage.

### Second Embodiment

Next, a semiconductor measurement device and a semiconductor measurement method according to a second embodiment will be described. FIGS. 11 and 12 are circuit diagrams illustrating the semiconductor measurement device 2 according to the second embodiment. The semiconductor measurement device 2 of the present embodiment may measure each capacitance of a plurality of measurement targets MTST as illustrated in FIG. 11, or may measure the capacitance of one measurement target MTST as illustrated in FIG. 12. Hereinafter, for convenience of description, description will be made using FIG. 12. In a case where the plurality of measurement targets MTST are measured, the plurality of measurement bodies DUT are arranged in parallel.

As illustrated in FIG. 12, the semiconductor measurement device 2 may include a measurement circuit SMUa, a measurement circuit SMUb, a switch terminal TSW2, a gate switch SWG2, an auxiliary terminal TH2 and an auxiliary switch SWH2, probe needles H1 and H2, and a control unit 20 in addition to a CBCM circuit 10 and a potential difference application circuit 13. Note that the semiconductor measurement device 2 may further include members other than the above members, or some of the above members may be omitted. The measurement circuit SMUb may be referred to as an auxiliary measurement circuit.

The measurement circuit SMUa is connected to a measurement terminal T04 of the CBCM circuit 10. The measurement circuit SMUa applies a voltage Vforce to the CBCM circuit 10 and measures a current Imeas via the measurement terminal T04.

The probe needle H1 and the probe needle H2 operate in conjunction with each other. The probe needle H1 connects a source terminal TS to the auxiliary terminal TH2 in a connected state. The probe needle H2 connects a gate terminal TG to the switch terminal TSW2 in the connected state. On the other hand, the probe needle H1 disconnects the source terminal TS from the auxiliary terminal TH2 in a disconnected state. The probe needle H2 disconnects the gate terminal TG from the switch terminal TSW2 in the disconnected state.

The switch terminal TSW2 is connected to the gate terminal TG in the connected state. The switch terminal TSW2 is disconnected from the gate terminal TG in the disconnected state. The auxiliary terminal TH2 is connected to the source terminal TS in the connected state. The auxiliary terminal TH2 is disconnected from the source terminal TS in the disconnected state. A first terminal T01 is connected to a drain terminal TD.

The gate switch SWG2 has one end and the other end. The one end of the gate switch SWG2 is fixed to the switch terminal TSW2. The other end of the gate switch SWG2 is connected to the second terminal T02 or the auxiliary terminal THO2. In this manner, the gate switch SWG2 connects the switch terminal TSW2 to the second terminal T02 or the auxiliary terminal TH2.

The measurement circuit SMUb is connected to the auxiliary switch SWH2. The auxiliary switch SWH2 is connected to the auxiliary terminal TH2. Thus, the auxiliary switch SWH2 connects the auxiliary terminal TH2 to the measurement circuit SMUb and disconnects the auxiliary terminal TH2 from the measurement circuit SMUb. When the auxiliary switch SWH2 is connected, the measurement circuit SMUb performs feedback control such that a current Iforce flowing through the auxiliary terminal TH2 becomes 0. In this manner, the measurement circuit SMUb that outputs a predetermined voltage to the auxiliary terminal TH2 may be further provided. The measurement circuit SMUb may have either a function of performing feedback control such that a current flowing through the auxiliary terminal TH2 becomes 0, or a function of having the auxiliary switch SWH2 that connects the auxiliary terminal TH2 to the measurement circuit SMUb and disconnects the auxiliary terminal TH2 from the measurement circuit SMUb.

The control unit 20 controls the operations of the gate switch SWG2, the auxiliary switch SWH2, the probe needles H1 and H2, the measurement circuit SMUa, and the measurement circuit SMUb. The control unit 20 may control the operation of the semiconductor measurement method described below.

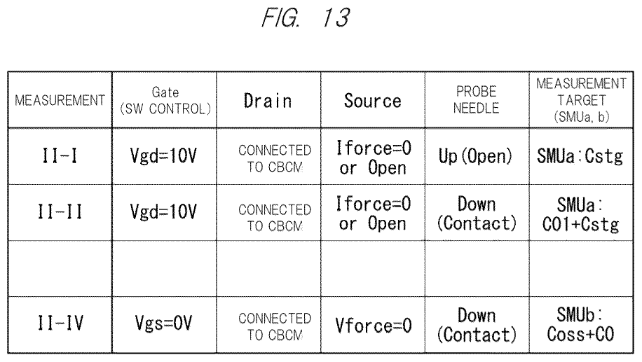

Next, the semiconductor measurement method for the measurement target MTST using the semiconductor measurement device 2 will be described. FIG. 13 is a diagram illustrating the semiconductor measurement method in the semiconductor measurement device 2 according to the second embodiment. As illustrated in FIG. 13, the semiconductor measurement method of the present embodiment includes a measurement II-I, a measurement II-II, and a measurement II-IV.

First, as illustrated in the measurement II-I in FIG. 13, the control unit 20 causes the gate switch SWG2 to connect the switch terminal TSW2 to the second terminal T02. Thus, when the probe needle H2 goes down, the gate terminal TG is connected to the switch terminal TSW2. As a result, an output of the second terminal T02 of the CBCM circuit 10 is applied to the gate G. For the output of the second terminal T02, a potential difference (for example, 10 V) with respect to the first terminal T01 is applied by the potential difference application circuit 13. As a result, when the probe needles H1 and H2 go down, a potential Vgd (for example, 10 V) is generated between the gate G and a drain D.

In addition, the drain terminal TD is connected to the first terminal T01 of the CBCM circuit 10. Thus, the output of the first terminal T01 of the CBCM circuit 10 is applied to the drain D. Furthermore, the control unit 20 causes the auxiliary terminal TH2 to be disconnected or causes the auxiliary switch SWH2 to be connected and the measurement circuit SMUb to perform feedback control. When the probe needle H1 goes down, the source terminal TS is connected to the auxiliary terminal TH2. When the auxiliary switch SWH2 is disconnected, a source S is open. When the auxiliary switch SWH2 is connected, the measurement circuit SMUb performs feedback control such that the current Iforce flowing through the auxiliary terminal TH2 becomes 0. As a result, a current becomes 0 at the source S. In this manner, the measurement circuit SMUb that outputs a predetermined voltage to the auxiliary terminal TH2 may be further provided. The measurement circuit SMUb may have either a function of performing feedback control such that the current flowing through the auxiliary terminal TH2 becomes 0, or a function of having the auxiliary switch SWH2 that connects the auxiliary terminal TH2 to the measurement circuit SMUb and disconnects the auxiliary terminal TH2 from the measurement circuit SMUb.

With such a configuration, the control unit 20 causes the probe needle H1 to go up to bring the source terminal TS and the auxiliary terminal TH2 into the disconnected state. In addition, the control unit 20 causes the probe needle H2 to go up to bring the gate terminal TG and the switch terminal TSW2 into the disconnected state. In this case, the control unit 20 causes the measurement circuit SMUa to measure a parasitic capacitance Cstg of a stage STG from a current flowing through the measurement terminal T04.

Next, as illustrated in the measurement II-II in FIG. 13, the control unit 20 causes the gate switch SWG2 to connect the switch terminal TSW2 to the second terminal T02. Thus, when the probe needle H2 goes down, the gate terminal TG is connected to the switch terminal TSW2. As a result, an output of the second terminal T02 of the CBCM circuit 10 is applied to the gate G.

In addition, the drain terminal TD is connected to the first terminal T01 of the CBCM circuit 10. Thus, the output of the first terminal T01 of the CBCM circuit 10 is applied to the drain D. Furthermore, the control unit 20 causes the auxiliary terminal TH2 to be disconnected or causes the auxiliary switch SWH2 to be connected and the measurement circuit SMUb to perform feedback control.

With such a configuration, the control unit 20 causes the probe needle H1 to go down to bring the source terminal TS and the auxiliary terminal TH2 into the connected state. In addition, the control unit 20 causes the probe needle H2 to go down to bring the gate terminal TG and the switch terminal TSW2 into the connected state. In this case, the control unit 20 causes the measurement circuit SMUa to measure a parasitic capacitance C01 of the plurality of measurement bodies DUT and a parasitic capacitance Cstg of the stage STG from a current flowing through the measurement terminal T04.

Next, as illustrated in the measurement II-IV in FIG. 13, the control unit 20 causes the gate switch SWG2 to connect the switch terminal TSW2 to the auxiliary terminal TH2. Thus, when the probe needle H2 goes down, the output of the measurement circuit SMUb is applied to the gate G via the auxiliary switch SWH2.

In addition, the drain D is connected to the first terminal T01 of the CBCM circuit 10. Thus, the output of the first terminal T01 of the CBCM circuit 10 is applied to the drain D. Furthermore, the control unit 20 causes the auxiliary switch SWH2 to be connected. Then, the control unit 20 causes the measurement circuit SMUb to output Vforce=0. As a result, when the probe needle H1 goes down, the source terminal TS is connected to the measurement circuit SMUb. Thus, Vforce=0 is applied to the source S.

With such a configuration, the control unit 20 causes the probe needle H1 to go down to bring the source terminal TS and the auxiliary terminal TH2 into the connected state. In addition, the control unit 20 causes the probe needle H2 to go down to bring the gate terminal TG and the switch terminal TSW2 into the connected state. In this case, the control unit 20 causes the measurement circuit SMUb to measure a capacitance Coss of a transistor MTR and a parasitic capacitance C0 of each measurement body DUT from a current flowing through each auxiliary terminal TH2 of each measurement body DUT.

From the measurement II-I and the measurement II-II, the semiconductor measurement device 2 can calculate the parasitic capacitance C01 of the plurality of the measurement bodies DUT. Here, a value obtained by dividing C01 by the number of the measurement bodies DUT in parallel can be approximately regarded as the parasitic capacitance C0 of each measurement body DUT. In addition, from the calculated parasitic capacitance C01 and the measurement I-IV, the semiconductor measurement device 2 can calculate the capacitance Coss of the transistor MTR according to (Capacitance Coss of the transistor MTR of each measurement body DUT and parasitic capacitance C0 of each measurement body DUT)—(Parasitic capacitance C01 of each measurement body DUT/Number of the measurement bodies DUT in parallel).

According to the present embodiment, even in a case where the CBCM circuit 10 is arranged on the stage side, the semiconductor measurement device 2 can suppress the occurrence of charging and discharging of parasitic capacitances Cgd and Cgs of the transistor MTR by driving the gate G of the transistor MTR that is the measurement target MTST. As a result, the accuracy in measuring the capacitance Coss of the transistor MTR can be improved. Other configurations and effects are included in the description of the first embodiment.

### Third Embodiment

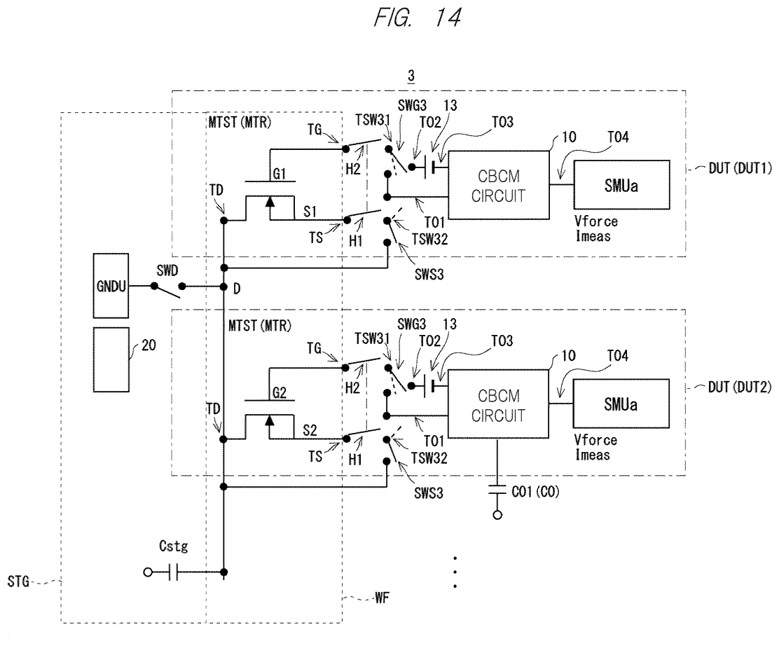

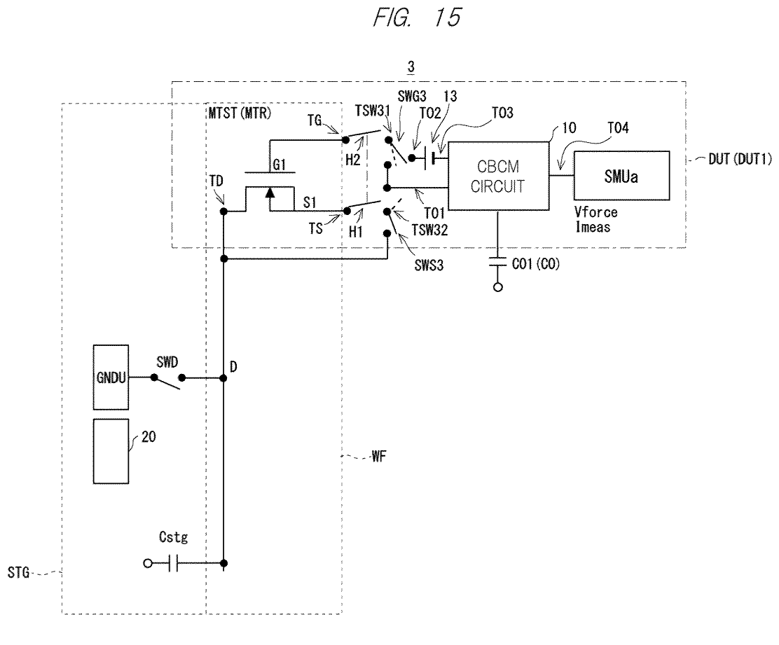

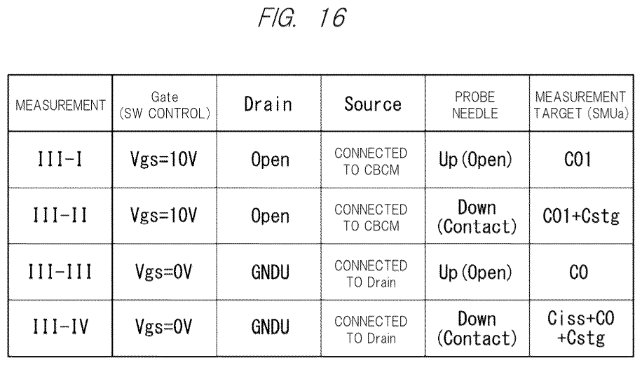

Next, a semiconductor measurement device and a semiconductor measurement method according to a third embodiment will be described. FIGS. 14 and 15 are circuit diagrams illustrating the semiconductor measurement device 3 according to the third embodiment. The semiconductor measurement device 3 may measure each capacitance of a plurality of measurement targets MTST as illustrated in FIG. 14, or may measure the capacitance of one measurement target MTST as illustrated in FIG. 15. Hereinafter, for convenience of description, description will be made using FIG. 15. In a case where the plurality of measurement targets MTST are measured, the plurality of measurement bodies DUT are arranged in parallel.

As illustrated in FIG. 15, the semiconductor measurement device 3 may include a switch terminal TSW31, a switch terminal TSW32, a gate switch SWG3, a source switch SWS3, a ground circuit GNDU, a drain switch SWD, probe needles H1 and H2, a measurement circuit SMUa, and a control unit 20 in addition to a CBCM circuit 10 and a potential difference application circuit 13. Note that the semiconductor measurement device 3 may further include members other than the above members, or some of the above members may be omitted. The source switch SWS3 may be referred to as a first region switch. Note that the source switch SWS3 may be replaced with a second region switch. The measurement circuit SMUa is connected to a measurement terminal T04 of the CBCM circuit 10. The measurement circuit SMUa applies a voltage Vforce to the CBCM circuit 10 and measures a current Imeas via the measurement terminal T04.

The probe needle H1 and the probe needle H2 operate in conjunction with each other. The probe needle H1 connects a source terminal TS to the switch terminal TSW32 in a connected state. The probe needle H2 connects a gate terminal TG to the switch terminal TSW31 in the connected state. On the other hand, the probe needle H1 disconnects the source terminal TS from the switch terminal TSW32 in a disconnected state. The probe needle H2 disconnects the gate terminal TG from the switch terminal TSW31 in the disconnected state.

The switch terminal TSW31 is connected to the gate terminal TG in the connected state. The switch terminal TSW31 is disconnected from the gate terminal TG in the disconnected state. The switch terminal TSW32 is connected to the source terminal TS in the connected state. The switch terminal TSW32 is disconnected from the source terminal TS in the disconnected state.

The gate switch SWG3 has one end and the other end. The one end of the gate switch SWG3 is fixed to the switch terminal TSW31. The other end of the gate switch SWG3 is connected to the first terminal T01 or the second terminal T02. In this manner, the gate switch SWG3 connects the switch terminal TSW31 to the first terminal T01 or the second terminal T02.

The source switch SWS3 has one end and the other end. The one end of the source switch SWS3 is fixed to the switch terminal TSW32. The other end of the source switch SWS3 is connected to the first terminal T01 or a drain terminal TD. In this manner, the source switch SWS3 connects the switch terminal TSW32 to the first terminal T01 or the drain terminal TD.

The drain terminal TD is connected to the drain switch SWD. The drain switch SWD is connected to a ground circuit GNDU. The ground circuit GNDU outputs a ground potential. The drain switch SWD connects the drain terminal TD to the ground circuit GNDU and disconnects the drain terminal TD from the ground circuit GNDU.

The control unit 20 controls the operations of the gate switch SWG3, the drain switch SWD, the source switch SWS3, the probe needles H1 and H2, and the measurement circuit SMUa. The control unit 20 may control the operation of the semiconductor measurement method described below.

Next, the semiconductor measurement method for the measurement target MTST using the semiconductor measurement device 3 will be described. FIG. 16 is a diagram illustrating the semiconductor measurement method in the semiconductor measurement device 3 according to the third embodiment. As illustrated in FIG. 16, the semiconductor measurement method of the present embodiment includes a measurement III-I, a measurement III-II, a measurement III-III, and a measurement III-IV.

First, as illustrated in the measurement III-I in FIG. 16, the control unit 20 causes the gate switch SWG3 to connect the switch terminal TSW31 to the second terminal T02. Thus, when the probe needle H2 goes down, the gate terminal TG is connected to the switch terminal TSW31. As a result, an output of the second terminal T02 of the CBCM circuit 10 is applied to the gate G.

In addition, the control unit 20 causes the source switch SWS3 to connect the switch terminal TSW32 to the first terminal T01. Thus, when the probe needle H1 goes down, the source terminal TS is connected to the first terminal T01. As a result, the output of the first terminal T01 of the CBCM circuit 10 is applied to a source S. Furthermore, the control unit 20 causes the drain switch SWD to be disconnected.

With such a configuration, the control unit 20 causes the probe needle H1 to go up to bring the source terminal TS and the switch terminal TSW32 into the disconnected state. In addition, the control unit 20 causes the probe needle H2 to go up to bring the gate terminal TG and the switch terminal TSW31 into the disconnected state. In this case, the control unit 20 causes the measurement circuit SMUa to measure a parasitic capacitance C01 of the plurality of measurement bodies DUT from the sum of currents flowing through the measurement terminals T04 of the respective measurement bodies DUT.

Next, as illustrated in the measurement III-II in FIG. 16, the control unit 20 causes the gate switch SWG3 to connect the switch terminal TSW31 to the second terminal T02. Thus, when the probe needle H2 goes down, the gate terminal TG is connected to the switch terminal TSW31. As a result, an output of the second terminal T02 of the CBCM circuit 10 is applied to the gate G.

In addition, the control unit 20 causes the source switch SWS3 to connect the switch terminal TSW32 to the first terminal T01. Thus, when the probe needle H1 goes down, the source terminal TS is connected to the first terminal T01. As a result, the output of the first terminal T01 of the CBCM circuit 10 is applied to a source S. Furthermore, the control unit 20 causes the drain switch SWD to be disconnected.

With such a configuration, the control unit 20 causes the probe needle H1 to go down to bring the source terminal TS and the switch terminal TSW32 into the connected state. In addition, the control unit 20 causes the probe needle H2 to go down to bring the gate terminal TG and the switch terminal TSW31 into the connected state. In this case, the control unit 20 causes the measurement circuit SMUa to measure the parasitic capacitance C01 of the plurality of measurement bodies DUT and a parasitic capacitance Cstg of the entire stage STG from the sum of the currents flowing through the measurement terminals T04 of the respective measurement bodies DUT.

Next, as illustrated in the measurement III-III in FIG. 16, the control unit 20 causes the gate switch SWG3 to connect the switch terminal TSW31 to the first terminal T01. Thus, when the probe needle H2 goes down, the gate terminal TG is connected to the first terminal T01. As a result, the output of the first terminal T01 of the CBCM circuit 10 is applied to the gate G.

In addition, the control unit 20 causes the source switch SWS3 to connect the switch terminal TSW32 to the drain terminal TD. As a result, when the probe needle H1 goes down, the source terminal TS is connected to the drain terminal TD. Furthermore, the control unit 20 causes the drain switch SWD to be connected. As a result, the ground potential is applied to a drain D via the drain terminal TD.

With such a configuration, the control unit 20 causes the probe needle H1 to go up to bring the source terminal TS and the switch terminal TSW32 into the disconnected state. In addition, the control unit 20 causes the probe needle H2 to go up to bring the gate terminal TG and the switch terminal TSW31 into the disconnected state. In this case, the control unit 20 causes the measurement circuit SMUa to measure parasitic capacitances C0 of each measurement body DUT from the current flowing through the measurement terminal T04 of the respective measurement bodies DUT.

Next, as illustrated in the measurement III-IV in FIG. 16, the control unit 20 causes the gate switch SWG3 to connect the switch terminal TSW31 to the first terminal T01. Thus, when the probe needle H2 goes down, the gate terminal TG is connected to the first terminal T01. As a result, the output of the first terminal T01 of the CBCM circuit 10 is applied to the gate G.

In addition, the control unit 20 causes the source switch SWS3 to connect the switch terminal TSW32 to the drain terminal TD. As a result, when the probe needle H1 goes down, the source terminal TS is connected to the drain terminal TD. Furthermore, the control unit 20 causes the drain switch SWD to be connected.

With such a configuration, the control unit 20 causes the probe needle H1 to go down to bring the source terminal TS and the switch terminal TSW32 into the connected state. In addition, the control unit 20 causes the probe needle H2 to go down to bring the gate terminal TG and the switch terminal TSW31 into the connected state. In this case, the control unit 20 causes the measurement circuit SMUa to measure a capacitance Ciss of a transistor MTR, the parasitic capacitance C0 of each measurement body DUT, and the parasitic capacitance Cstg of the stage from the current flowing through each measurement terminal T04 of each measurement body DUT.

From the measurement III-I and the measurement III-II, the semiconductor measurement device 3 can calculate the parasitic capacitance Cstg of the entire stage STG. Here, a value obtained by dividing the parasitic capacitance Cstg of the entire stage STG by the number of the measurement bodies DUT in parallel can be approximately regarded as the parasitic capacitance Cstg of the stage STG of each measurement body DUT. In addition, the parasitic capacitance C0 of each measurement body DUT can be calculated from the measurement III-III. Furthermore, from the parasitic capacitance Cstg and the parasitic capacitance C0 obtained from the measurement III-I, the measurement III-II, and the measurement III-III, and the measurement III-IV, the semiconductor measurement device 3 can calculate the capacitance Ciss of the transistor MTR of each measurement body DUT. Specifically, the semiconductor measurement device 3 can calculate the capacitance Ciss of the transistor MTR from: (Capacitance Ciss of the transistor MTR of each measurement body DUT, parasitic capacitance C0 of each measurement body DUT, and parasitic capacitance Cstg of the stage STG)—(Parasitic capacitance C0 of each measurement body DUT)—(Parasitic capacitance Cstg of the entire stage STG/Number of the measurement bodies DUT in parallel).

According to the present embodiment, the capacitance Ciss of the transistor MTR of the measurement target MTST can be measured with high accuracy. Other configurations and effects are included in the description of the first and second embodiments.

### Fourth Embodiment

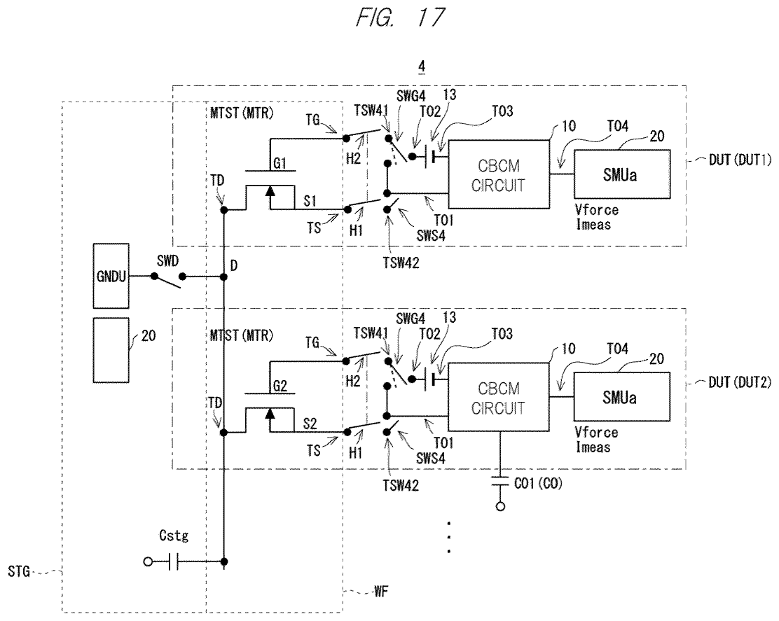

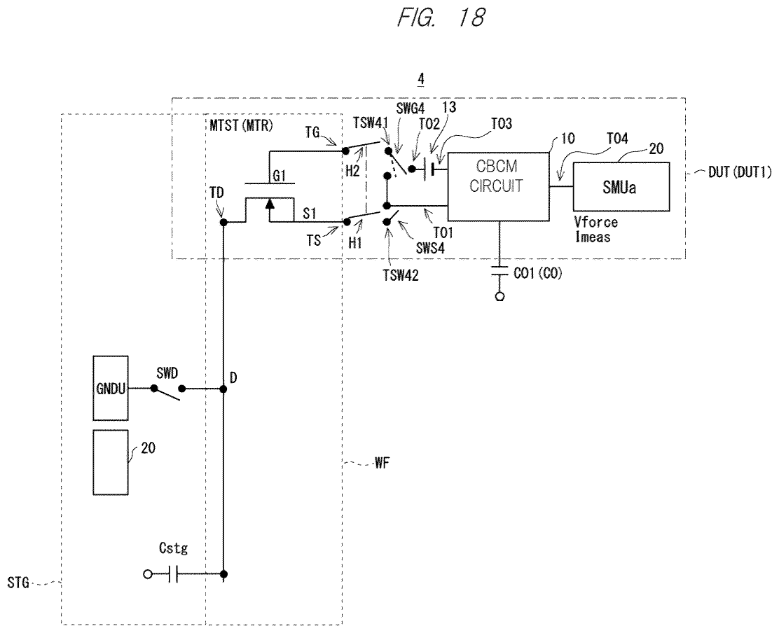

Next, a semiconductor measurement device and a semiconductor measurement method according to a fourth embodiment will be described. FIGS. 17 and 18 are circuit diagrams illustrating the semiconductor measurement device 4 according to the fourth embodiment. The semiconductor measurement device 4 may measure each capacitance of a plurality of measurement targets MTST as illustrated in FIG. 17, or may measure the capacitance of one measurement target MTST as illustrated in FIG. 18. Hereinafter, for convenience of description, description will be made using FIG. 18. In a case where the plurality of measurement targets MTST are measured, the plurality of measurement bodies DUT are arranged in parallel.

As illustrated in FIG. 18, the semiconductor measurement device 4 may include a switch terminal TSW41, a switch terminal TSW42, a gate switch SWG4, a source switch SWS4, a ground circuit GNDU, a drain switch SWD, probe needles H1 and H2, a measurement circuit SMUa, and a control unit 20 in addition to a CBCM circuit 10 and a potential difference application circuit 13. Note that the semiconductor measurement device 4 may further include members other than the above members, or some of the above members may be omitted. The measurement circuit SMUa is connected to a measurement terminal T04 of the CBCM circuit 10. The measurement circuit SMUa applies a voltage Vforce to the CBCM circuit 10 and measures a current Imeas via the measurement terminal T04.

The probe needle H1 and the probe needle H2 operate in conjunction with each other. The probe needle H1 connects a source terminal TS to the switch terminal TSW42 in a connected state. The probe needle H2 connects a gate terminal TG to the switch terminal TSW41 in the connected state. On the other hand, the probe needle H1 disconnects the source terminal TS from the switch terminal TSW42 in a disconnected state. The probe needle H2 disconnects the gate terminal TG from the switch terminal TSW41 in the disconnected state.

The switch terminal TSW41 is connected to the gate terminal TG in the connected state. The switch terminal TSW41 is disconnected from the gate terminal TG in the disconnected state. The switch terminal TSW42 is connected to the source terminal TS in the connected state. The switch terminal TSW42 is disconnected from the source terminal TS in the disconnected state.

The gate switch SWG4 has one end and the other end. The one end of the gate switch SWG4 is fixed to the switch terminal TSW41. The other end of the gate switch SWG4 is connected to the first terminal T01 or the second terminal T02. In this manner, the gate switch SWG4 connects the switch terminal TSW41 to the first terminal T01 or the second terminal T02.

The source switch SWS4 connects the switch terminal TSW42 to the first terminal T01 and disconnects the switch terminal TSW42 from the first terminal T01. A drain terminal TD is connected to the drain switch SWD. The drain switch SWD is connected to a ground circuit GNDU. The ground circuit GNDU outputs a ground potential. The drain switch SWD connects the drain terminal TD to the ground circuit GNDU and disconnects the drain terminal TD from the ground circuit GNDU.

The control unit 20 controls the operations of the gate switch SWG4, the drain switch SWD, the source switch SWS4, the probe needles H1 and H2, and the measurement circuit SMUa. The control unit 20 may control the operation of the semiconductor measurement method described below.

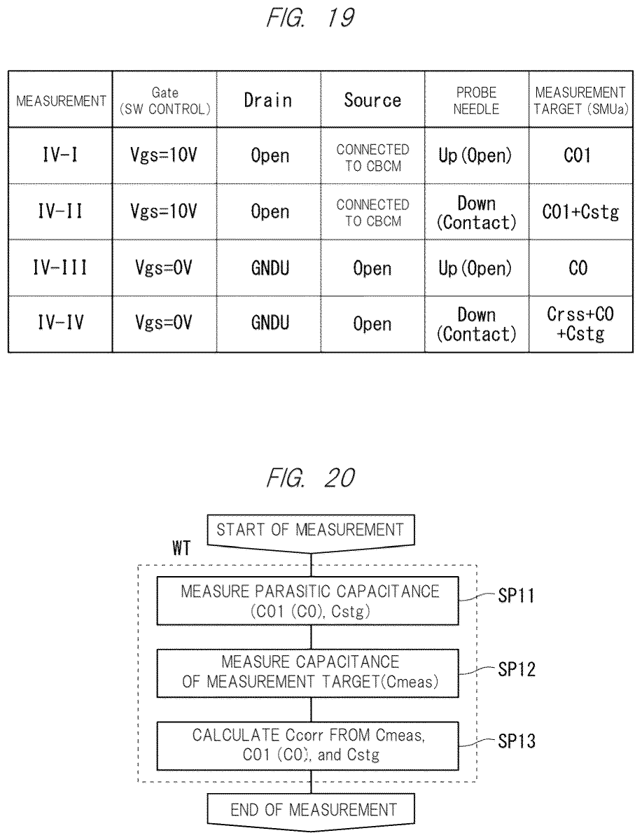

Next, the semiconductor measurement method for the measurement target MTST using the semiconductor measurement device 4 will be described. FIG. 19 is a diagram illustrating the semiconductor measurement method in the semiconductor measurement device 4 according to the fourth embodiment. As illustrated in FIG. 19, the semiconductor measurement method of the present embodiment includes a measurement IV-I, a measurement IV-II, a measurement IV-III, and a measurement IV-IV.

First, as illustrated in the measurement IV-I in FIG. 19, the control unit 20 causes the gate switch SWG4 to connect the switch terminal TSW41 to the second terminal T02. Thus, when the probe needle H2 goes down, the gate terminal TG is connected to the switch terminal TSW41. As a result, an output of the second terminal T02 of the CBCM circuit 10 is applied to the gate G.

In addition, the control unit 20 causes the source switch SWS4 to connect the switch terminal TSW42 to the first terminal T01. Thus, when the probe needle H1 goes down, the source terminal TS is connected to the first terminal T01. As a result, the output of the first terminal T01 of the CBCM circuit 10 is applied to a source S. Furthermore, the control unit 20 causes the drain switch SWD to be disconnected.

With such a configuration, the control unit 20 causes the probe needle H1 to go up to bring the source terminal TS and the switch terminal TSW42 into the disconnected state. In addition, the control unit 20 causes the probe needle H2 to go up to bring the gate terminal TG and the switch terminal TSW41 into the disconnected state. In this case, the control unit 20 causes the measurement circuit SMUa to measure a parasitic capacitance C01 of the plurality of measurement bodies DUT from the sum of currents flowing through the measurement terminals T04 of the respective measurement bodies DUT.

Next, as illustrated in the measurement IV-II in FIG. 19, the control unit 20 causes the gate switch SWG4 to connect the switch terminal TSW41 to the second terminal T02. Thus, when the probe needle H2 goes down, the gate terminal TG is connected to the switch terminal TSW41. As a result, an output of the second terminal T02 of the CBCM circuit 10 is applied to the gate G.

In addition, the control unit 20 causes the source switch SWS4 to connect the switch terminal TSW42 to the first terminal T01. Thus, when the probe needle H1 goes down, the source terminal TS is connected to the first terminal T01. As a result, the output of the first terminal T01 of the CBCM circuit 10 is applied to the source S. Furthermore, the control unit 20 causes the drain switch SWD to be disconnected.

With such a configuration, the control unit 20 causes the probe needle H1 to go down to bring the source terminal TS and the switch terminal TSW42 into the connected state. In addition, the control unit 20 causes the probe needle H2 to go down to bring the gate terminal TG and the switch terminal TSW41 into the connected state. In this case, the control unit 20 causes the measurement circuit SMUa to measure the parasitic capacitance C01 of the plurality of measurement bodies DUT and a parasitic capacitance Cstg of the entire stage STG from the sum of the currents flowing through the measurement terminals T04 of the respective measurement bodies DUT.

Next, as illustrated in the measurement IV-III in FIG. 19, the control unit 20 causes the gate switch SWG4 to connect the switch terminal TSW41 to the first terminal T01. Thus, when the probe needle H2 goes down, the gate terminal TG is connected to the first terminal T01. As a result, the output of the first terminal T01 of the CBCM circuit 10 is applied to the gate G.

In addition, the control unit 20 causes the source switch SWS4 to disconnect the switch terminal TSW42 from the first terminal T01. Furthermore, the control unit 20 causes the drain switch SWD to be connected. As a result, the ground potential is applied to a drain D via the drain terminal TD.

With such a configuration, the control unit 20 causes the probe needle H1 to go up to bring the source terminal TS and the switch terminal TSW42 into the disconnected state. In addition, the control unit 20 causes the probe needle H2 to go up to bring the gate terminal TG and the switch terminal TSW41 into the disconnected state. In this case, the control unit 20 causes the measurement circuit SMUa to measure parasitic capacitances C0 of each measurement body DUT from the current flowing through the measurement terminal T04 of the respective measurement bodies DUT.

Next, as illustrated in the measurement IV-IV in FIG. 19, the control unit 20 causes the gate switch SWG4 to connect the switch terminal TSW41 to the first terminal T01. Thus, when the probe needle H2 goes down, the gate terminal TG is connected to the first terminal T01. As a result, the output of the first terminal T01 of the CBCM circuit 10 is applied to the gate G.

In addition, the control unit 20 causes the source switch SWS4 to disconnect the switch terminal TSW42 from the first terminal T01. Furthermore, the control unit 20 causes the drain switch SWD to be connected.

With such a configuration, the control unit 20 causes the probe needle H1 to go down to bring the source terminal TS and the switch terminal TSW42 into the connected state. In addition, the control unit 20 causes the probe needle H2 to go down to bring the gate terminal TG and the switch terminal TSW41 into the connected state. In this case, the control unit 20 causes the measurement circuit SMUa to measure a capacitance Crss of a transistor MTR, the parasitic capacitance C0 of each measurement body DUT, and the parasitic capacitance Cstg of the stage from the current flowing through each measurement terminal T04 of each measurement body DUT.

From the measurement IV-I and the measurement IV-II, the semiconductor measurement device 4 can calculate the parasitic capacitance Cstg of the entire stage STG. Here, a value obtained by dividing the parasitic capacitance Cstg of the entire stage STG by the number of the measurement bodies DUT in parallel can be approximately regarded as the parasitic capacitance Cstg of the stage STG of each measurement body DUT. In addition, the parasitic capacitance C0 of each measurement body DUT can be calculated from the measurement IV-III. Furthermore, from the parasitic capacitance Cstg and the parasitic capacitance C0 obtained from the measurement IV-I, the measurement IV-II, and the measurement IV-III, and the measurement IV-IV, the semiconductor measurement device 4 can calculate the capacitance Crss of the transistor MTR of each measurement body DUT. Specifically, the semiconductor measurement device 4 can calculate the capacitance Crss of the transistor MTR from: (Capacitance Crss of the transistor MTR of each measurement body DUT, parasitic capacitance C0 of each measurement body DUT, and parasitic capacitance Cstg of the stage STG)—(Parasitic capacitance C0 of each measurement body DUT)—(Parasitic capacitance Cstg of the entire stage STG/Number of the measurement bodies DUT in parallel).

According to the present embodiment, the capacitance Crss of the transistor MTR of the measurement target MTST can be measured with high accuracy. Other configurations and effects are included in the description of the first to third embodiments.

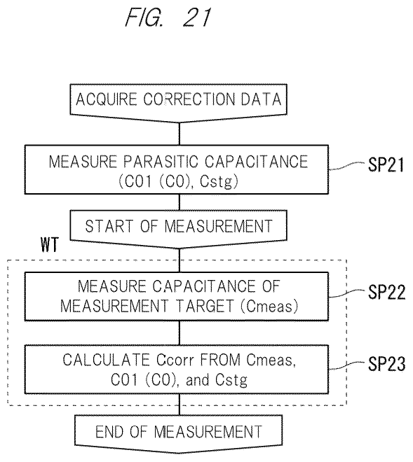

Next, the semiconductor measurement methods of the first to fourth embodiments will be described from another viewpoint. FIGS. 20 and 21 are flow chart diagrams illustrating a semiconductor measurement method in the semiconductor measurement devices according to the first to fourth embodiments. As illustrated in FIG. 20, the semiconductor measurement method according to the present embodiment includes a measurement step SP11 of a parasitic capacitance (C01 (C0), Cstg), a measurement step SP12 of a measurement target capacitance (Cmeas), and a step SP13 of measuring a capacitance excluding the parasitic capacitance (Ccorr). For example, in the measurement steps SP11 and SP12, the capacitance in the connected state in which the first terminal T01 and the second terminal T02 are connected to the transistor MTR, and the capacitance in the disconnected state in which the first terminal T01 and the second terminal T02 are disconnected from the transistor MTR are measured. Then, in the calculation step SP13, the capacitance of the transistor MTR is calculated from these measured capacitances. In this manner, in the semiconductor measurement method of the present embodiment, the capacitance of the measurement target MTST may be measured at every wafer test (WT) measurement.

In a case where the parasitic capacitance of the measurement target MTST does not fluctuate until the configuration of the semiconductor measurement device is changed, the parasitic capacitance (COl (C0), Cstg) of the measurement target MTST may be measured and recorded in advance as illustrated in step SP21 of FIG. 21. Then, when the measurement target MTST is measured during the wafer test, a measurement step SP22 of the capacitance of the measurement target (Cmeas) and a step SP23 of measuring the capacitance excluding the parasitic capacitance (Ccorr) may be performed. In this manner, a flow in which the parasitic capacitance of the measurement target MTST is not measured can be used during the wafer test.

Although the disclosure made by the present inventor has been specifically described based on the embodiments, it needless to say that the present disclosure is not limited to the above-described embodiments and various modifications can be made without departing from the gist of the present disclosure. For example, an appropriate combination of the configurations of Comparative Example 1 to 2 and the first to fourth embodiments is also within the scope of the technical idea of the embodiment. In addition, the following configurations are also within the scope of the technical idea of the embodiment.

### Appendix 1

A semiconductor measurement method using a semiconductor measurement device including:
a CBCM circuit having a first terminal and a connection terminal; and
a potential difference application circuit connected to the connection terminal, the potential difference application circuit having a second terminal and applying a predetermined potential difference with respect to an output of the first terminal, the method including:
obtaining a parasitic capacitance of a measurement system from a capacitance in a connected state in which the first terminal and the second terminal are connected to a transistor and a capacitance in a disconnected state in which the first terminal and the second terminal are disconnected from the transistor, and calculating a capacitance of the transistor.

### Appendix 2

The semiconductor measurement method according to Appendix 1,
wherein the semiconductor measurement device further includes:
a switch terminal connected to a gate terminal that is a terminal of a gate or base of the transistor in the connected state;
a gate switch that connects the switch terminal to the first terminal or the second terminal;
a ground circuit that outputs a ground potential;
a second region switch that connects a second region terminal that is a terminal of a second region of the transistor to the ground circuit and disconnects the second region terminal from the ground circuit; and
a control unit that controls the gate switch and the second region switch,
wherein, when the capacitance of the transistor is measured,
a first capacitance is measured by causing the gate switch to connect the switch terminal to the second terminal, causing the second region switch to be disconnected, bringing the first terminal and a first region terminal that is a terminal of a first region of the transistor into the disconnected state, and bringing the gate terminal and the switch terminal into the disconnected state,
a second capacitance is measured by causing the gate switch to connect the switch terminal to the second terminal, causing the second region switch to be disconnected, bringing the first terminal and the first region terminal into the connected state, and bringing the gate terminal and the switch terminal into the connected state,
a third capacitance is measured by causing the gate switch to connect the switch terminal to the first terminal, causing the second region switch to be connected, bringing the first terminal and the first region terminal into the disconnected state, and bringing the gate terminal and the switch terminal into the disconnected state,
a fourth capacitance is measured by causing the gate switch to connect the switch terminal to the first terminal, causing the second region switch to be connected, bringing the first terminal and the first region terminal into the connected state, and bringing the gate terminal and the switch terminal into the connected state, and
the capacitance of the transistor is calculated from the first capacitance, the second capacitance, the third capacitance, and the fourth capacitance.

### Appendix 3

The semiconductor measurement method according to Appendix 1,
wherein the semiconductor measurement device further includes:
an auxiliary terminal connected to a first region terminal that is a terminal of a first region of the transistor in the connected state;
an auxiliary measurement circuit that performs feedback control such that a current flowing through the auxiliary terminal becomes 0;
an auxiliary switch that connects the auxiliary terminal to the auxiliary measurement circuit and disconnects the auxiliary terminal from the auxiliary measurement circuit;
a switch terminal connected to a gate terminal that is a terminal of a gate or base of the transistor in the connected state;
a gate switch that causes the switch terminal to be connected to the second terminal or the auxiliary terminal; and
a control unit that controls the gate switch, the auxiliary switch, and the auxiliary measurement circuit, and
wherein the first terminal is connected to a second region terminal that is a terminal of a second region of the transistor, and
when the capacitance of the transistor is measured,
a first capacitance is measured by causing the gate switch to connect the switch terminal to the second terminal, causing the auxiliary switch to be disconnected or causing the auxiliary switch to be connected to cause the auxiliary measurement circuit to perform feedback control, bringing the first region terminal and the auxiliary terminal into the disconnected state, and bringing the gate terminal and the switch terminal into the disconnected state,
a second capacitance is measured by causing the gate switch to connect the switch terminal to the second terminal, causing the auxiliary switch to be disconnected or causing the auxiliary switch to be connected to cause the auxiliary measurement circuit to perform feedback control, bringing the first region terminal and the auxiliary terminal into the connected state, and bringing the gate terminal and the switch terminal into the connected state,
a third capacitance is measured by causing the gate switch to connect the switch terminal to the auxiliary terminal, causing the auxiliary switch to be connected, causing the auxiliary measurement circuit to output a predetermined voltage, bringing the first region terminal and the auxiliary terminal into the connected state, and bringing the gate terminal and the switch terminal into the connected state, and
the capacitance of the transistor is calculated from the first capacitance, the second capacitance, and the third capacitance.

### Appendix 4

The semiconductor measurement method according to Appendix 1,
wherein the semiconductor measurement device further includes:
a first switch terminal connected to a gate terminal that is a terminal of a gate or base of the transistor in the connected state;
a gate switch that causes the first switch terminal to be connected to the first terminal or the second terminal; a second switch terminal connected to a first region terminal that is a terminal of a first region of the transistor in the connected state;
a first region switch that causes the second switch terminal to be connected to a second region terminal that is a terminal of a second region of the transistor or the first terminal;
a ground circuit that outputs a ground potential;
a second region switch that connects the second region terminal to the ground circuit and disconnects the second region terminal from the ground circuit; and
a control unit that controls the gate switch, the first region switch, and the second region switch, and
wherein, when the capacitance of the transistor is measured,
a first capacitance is measured by causing the gate switch to connect the first switch terminal to the second terminal, causing the first region switch to connect the second switch terminal to the first terminal, causing the second region switch to be disconnected, bringing the second switch terminal and the first region terminal into the disconnected state, and bringing the gate terminal and the first switch terminal into the disconnected state,
a second capacitance is measured by causing the gate switch to connect the first switch terminal to the second terminal, causing the first region switch to connect the second switch terminal to the first terminal, causing the second region switch to be disconnected, bringing the second switch terminal and the first region terminal into the connected state, and bringing the gate terminal and the first switch terminal into the connected state,
a third capacitance is measured by causing the gate switch to connect the first switch terminal to the first terminal, causing the first region switch to connect the second switch terminal to the second region terminal, causing the second region switch to be connected, bringing the second switch terminal and the first region terminal into the disconnected state, and bringing the gate terminal and the first switch terminal into the disconnected state,
a fourth capacitance is measured by causing the gate switch to connect the first switch terminal to the first terminal, causing the first region switch to connect the second switch terminal to the second region terminal, causing the second region switch to be connected, bringing the second switch terminal and the first region terminal into the connected state, and bringing the gate terminal and the first switch terminal into the connected state, and
the capacitance of the transistor is calculated from the first capacitance, the second capacitance, the third capacitance, and the fourth capacitance.

### Appendix 5

The semiconductor measurement method according to Appendix 1,
wherein the semiconductor measurement device further includes:
a first switch terminal connected to a gate terminal that is a terminal of a gate or base of the transistor in the connected state;
a gate switch that causes the first switch terminal to be connected to the first terminal or the second terminal;
a second switch terminal connected to a first region terminal that is a terminal of a first region of the transistor in the connected state;
a first region switch that connects the second switch terminal to the first terminal and disconnects the second switch terminal from the first terminal;
a ground circuit that outputs a ground potential; and
a second region switch that connects a second region terminal that is a terminal of a second region of the transistor to the ground circuit and disconnects the second region terminal from the ground circuit, and
wherein, when the capacitance of the transistor is measured,
a first capacitance is measured by causing the gate switch to connect the first switch terminal to the second terminal, causing the first region switch to be connected, causing the second region switch to be disconnected, bringing the second switch terminal and the first region terminal into the disconnected state, and bringing the gate terminal and the first switch terminal into the disconnected state,
a second capacitance is measured by causing the gate switch to connect the first switch terminal to the second terminal, causing the first region switch to be connected, causing the second region switch to be disconnected, bringing the second switch terminal and the first region terminal into the connected state, and bringing the gate terminal and the first switch terminal into the connected state,
a third capacitance is measured by causing the gate switch to connect the first switch terminal to the first terminal, causing the first region switch to be disconnected, causing the second region switch to be connected, bringing the second switch terminal and the first region terminal into the disconnected state, and bringing the gate terminal and the first switch terminal into the disconnected state,
a fourth capacitance is measured by causing the gate switch to connect the first switch terminal to the first terminal, causing the first region switch to be disconnected, causing the second region switch to be connected, bringing the second switch terminal and the first region terminal into the connected state, and bringing the gate terminal and the first switch terminal into the connected state, and
the capacitance of the transistor is calculated from the first capacitance, the second capacitance, the third capacitance, and the fourth capacitance.

What is claimed is:

1. semiconductor measurement device comprising:
a CBCM circuit having a first terminal and a connection terminal; and
a potential difference application circuit connected to the connection terminal, the potential difference application circuit having a second terminal and applying a predetermined potential difference with respect to an output of the first terminal,
wherein the semiconductor measurement device obtains a parasitic capacitance of a measurement system from a capacitance in a connected state in which the first terminal and the second terminal are connected to a transistor and a capacitance in a disconnected state in which the first terminal and the second terminal are disconnected from the transistor, and calculates a capacitance of the transistor.

2. The semiconductor measurement device according to claim 1, further comprising
a probe needle that switches between the connected state and the disconnected state.

3. The semiconductor measurement device according to claim 1, further comprising:
a switch terminal connected to a gate terminal that is a terminal of a gate or base of the transistor in the connected state; and
a gate switch that causes the switch terminal to be connected to the first terminal or the second terminal.

4. The semiconductor measurement device according to claim 1,
wherein the first terminal is connected to a first region terminal that is a terminal of a first region of the transistor in the connected state.

5. The semiconductor measurement device according to claim 4,
wherein the first region includes a source or an emitter.

6. The semiconductor measurement device according to claim 1, further comprising:
a ground circuit that outputs a ground potential; and
a second region switch that connects a second region terminal that is a terminal of a second region of the transistor to the ground circuit, and disconnects the second region terminal from the ground circuit.

7. The semiconductor measurement device according to claim 6,
wherein the second region includes a drain or a collector.

8. The semiconductor measurement device according to claim 1,
wherein the CBCM circuit further includes a measurement terminal, and
wherein the semiconductor measurement device further comprises a measurement circuit connected to the measurement terminal, the measurement circuit applying a voltage to the CBCM circuit via the measurement terminal and measuring a current.

9. The semiconductor measurement device according to claim 1,
wherein the CBCM circuit includes:
a charging transistor that outputs a predetermined charge voltage to the transistor via the first terminal and the second terminal; and
a discharging transistor that outputs a predetermined discharge voltage to the transistor via the first terminal and the second terminal.

10. The semiconductor measurement device according to claim 1, further comprising:
a switch terminal connected to a gate terminal that is a terminal of a gate or base of the transistor in the connected state;
a gate switch that connects the switch terminal to the first terminal or the second terminal;
a ground circuit that outputs a ground potential;
a second region switch that connects a second region terminal that is a terminal of a second region of the transistor to the ground circuit and disconnects the second region terminal from the ground circuit; and
a control unit that controls the gate switch and the second region switch,
wherein the control unit causes:
a first capacitance to be measured by causing the gate switch to connect the switch terminal to the second terminal, causing the second region switch to be disconnected, bringing the first terminal and a first region terminal that is a terminal of a first region of the transistor into the disconnected state, and bringing the gate terminal and the switch terminal into the disconnected state;
a second capacitance to be measured by causing the gate switch to connect the switch terminal to the second terminal, causing the second region switch to be disconnected, bringing the first terminal and the first region terminal into the connected state, and bringing the gate terminal and the switch terminal into the connected state;
a third capacitance to be measured by causing the gate switch to connect the switch terminal to the first terminal, causing the second region switch to be connected, bringing the first terminal and the first region terminal into the disconnected state, and bringing the gate terminal and the switch terminal into the disconnected state;
a fourth capacitance to be measured by causing the gate switch to connect the switch terminal to the first terminal, causing the second region switch to be connected, bringing the first terminal and the first region terminal into the connected state, and bringing the gate terminal and the switch terminal into the connected state; and
the capacitance of the transistor to be calculated from the first capacitance, the second capacitance, the third capacitance, and the fourth capacitance.

11. The semiconductor measurement device according to claim 1,
wherein the first terminal is connected to a second region terminal that is a terminal of a second region of the transistor.

12. The semiconductor measurement device according to claim 1, further comprising:
an auxiliary terminal connected to a first region terminal that is a terminal of a first region of the transistor in the connected state;
a switch terminal connected to a gate terminal that is a terminal of a gate or base of the transistor in the connected state; and
a gate switch that causes the switch terminal to be connected to the second terminal or the auxiliary terminal.

13. The semiconductor measurement device according to claim 12, further comprising
an auxiliary measurement circuit that outputs a predetermined voltage to the auxiliary terminal,
wherein the auxiliary measurement circuit has either a function of performing feedback control such that a current flowing through the auxiliary terminal becomes 0 or a function of having an auxiliary switch that connects the auxiliary terminal to the auxiliary measurement circuit and disconnects the auxiliary terminal from the auxiliary measurement circuit.

14. The semiconductor measurement device according to claim 1, further comprising:
an auxiliary terminal connected to a first region terminal that is a terminal of a first region of the transistor in the connected state;
an auxiliary measurement circuit that outputs a predetermined voltage to the auxiliary terminal, the auxiliary measurement circuit having either a function of performing feedback control such that a current flowing through the auxiliary terminal becomes 0, or a function of having an auxiliary switch that connects the auxiliary terminal to the auxiliary measurement circuit and disconnects the auxiliary terminal from the auxiliary measurement circuit;
a switch terminal connected to a gate terminal that is a terminal of a gate or base of the transistor in the connected state;
a gate switch that causes the switch terminal to be connected to the second terminal or the auxiliary terminal; and
a control unit that controls the gate switch, the auxiliary switch, and the auxiliary measurement circuit,
wherein the first terminal is connected to a second region terminal that is a terminal of a second region of the transistor, and
wherein the control unit causes:
a first capacitance to be measured by causing the gate switch to connect the switch terminal to the second terminal, causing the auxiliary switch to be disconnected or causing the auxiliary measurement circuit to perform feedback control, bringing the first region terminal and the auxiliary terminal into the disconnected state, and bringing the gate terminal and the switch terminal into the disconnected state;
a second capacitance to be measured by causing the gate switch to connect the switch terminal to the second terminal, causing the auxiliary switch to be disconnected or causing the auxiliary measurement circuit to perform feedback control, bringing the first region terminal and the auxiliary terminal into the connected state, and bringing the gate terminal and the switch terminal into the connected state;
a third capacitance to be measured by causing the gate switch to connect the switch terminal to the auxiliary terminal, causing the auxiliary terminal and the auxiliary measurement circuit into the connected state, causing the auxiliary measurement circuit to output a predetermined voltage, bringing the first region terminal and the auxiliary terminal into the connected state, and bringing the gate terminal and the switch terminal into the connected state; and
the capacitance of the transistor to be calculated from the first capacitance, the second capacitance, and the third capacitance.

15. The semiconductor measurement device according to claim 1, further comprising:
a first switch terminal connected to a gate terminal that is a terminal of a gate or base of the transistor in the connected state;
a gate switch that causes the first switch terminal to be connected to the first terminal or the second terminal;
a second switch terminal connected to a first region terminal that is a terminal of a first region of the transistor in the connected state; and
a first region switch that connects the second switch terminal to a second region terminal that is a terminal of a second region of the transistor or the first terminal.

16. The semiconductor measurement device according to claim 1, further comprising:
a first switch terminal connected to a gate terminal that is a terminal of a gate or base of the transistor in the connected state;
a gate switch that causes the first switch terminal to be connected to the first terminal or the second terminal;
a second switch terminal connected to a first region terminal that is a terminal of a first region of the transistor in the connected state;
a first region switch that causes the second switch terminal to be connected to a second region terminal that is a terminal of a second region of the transistor or the first terminal;
a ground circuit that outputs a ground potential;
a second region switch that connects the second region terminal to the ground circuit and disconnects the second region terminal from the ground circuit; and
a control unit that controls the gate switch, the first region switch, and the second region switch,
wherein the control unit causes:
a first capacitance to be measured by causing the gate switch to connect the first switch terminal to the second terminal, causing the first region switch to connect the second switch terminal to the first terminal, causing the second region switch to be disconnected, bringing the second switch terminal and the first region terminal into the disconnected state, and bringing the gate terminal and the first switch terminal into the disconnected state;
a second capacitance to be measured by causing the gate switch to connect the first switch terminal to the second terminal, causing the first region switch to connect the second switch terminal to the first terminal, causing the second region switch to be disconnected, bringing the second switch terminal and the first region terminal into the connected state, and bringing the gate terminal and the first switch terminal into the connected state;
a third capacitance to be measured by causing the gate switch to connect the first switch terminal to the first terminal, causing the first region switch to connect the second switch terminal to the second region terminal, causing the second region switch to be connected, bringing the second switch terminal and the first region terminal into the disconnected state, and bringing the gate terminal and the first switch terminal into the disconnected state;
a fourth capacitance to be measured by causing the gate switch to connect the first switch terminal to the first terminal, causing the first region switch to connect the second switch terminal to the second region terminal, causing the second region switch to be connected, bringing the second switch terminal and the first region terminal into the connected state, and bringing the gate terminal and the first switch terminal into the connected state; and
the capacitance of the transistor to be calculated from the first capacitance, the second capacitance, the third capacitance, and the fourth capacitance.

17. The semiconductor measurement device according to claim 1, further comprising:
a first switch terminal connected to a gate terminal that is a terminal of a gate or base of the transistor in the connected state;
a gate switch that causes the first switch terminal to be connected to the first terminal or the second terminal;
a second switch terminal connected to a first region terminal that is a terminal of a first region of the transistor in the connected state; and
a first region switch that connects the second switch terminal to the first terminal and disconnects the second switch terminal from the first terminal.

18. The semiconductor measurement device according to claim 1, further comprising:
a first switch terminal connected to a gate terminal that is a terminal of a gate or base of the transistor in the connected state;
a gate switch that causes the first switch terminal to be connected to the first terminal or the second terminal;
a second switch terminal connected to a first region terminal that is a terminal of a first region of the transistor in the connected state;
a first region switch that connects the second switch terminal to the first terminal and disconnects the second switch terminal from the first terminal;
a ground circuit that outputs a ground potential;
a second region switch that connects a second region terminal that is a terminal of a second region of the transistor to the ground circuit and disconnects the second region terminal from the ground circuit; and
a control unit that controls the gate switch, the first region switch, and the second region switch,
wherein the control unit causes:
a first capacitance to be measured by causing the gate switch to connect the first switch terminal to the second terminal, causing the first region switch to be connected, causing the second region switch to be disconnected, bringing the second switch terminal and the first region terminal into the disconnected state, and bringing the gate terminal and the first switch terminal into the disconnected state;
a second capacitance to be measured by causing the gate switch to connect the first switch terminal to the second terminal, causing the first region switch to be connected, causing the second region switch to be disconnected, bringing the second switch terminal and the first region terminal into the connected state, and bringing the gate terminal and the first switch terminal into the connected state;
a third capacitance to be measured by causing the gate switch to connect the first switch terminal to the first terminal, causing the first region switch to be disconnected, causing the second region switch to be connected, bringing the second switch terminal and the first region terminal into the disconnected state, and bringing the gate terminal and the first switch terminal into the disconnected state;
a fourth capacitance to be measured by causing the gate switch to connect the first switch terminal to the first terminal, causing the first region switch to be disconnected, causing the second region switch to be connected, bringing the second switch terminal and the first region terminal into the connected state, and bringing the gate terminal and the first switch terminal into the connected state; and
the capacitance of the transistor to be calculated from the first capacitance, the second capacitance, the third capacitance, and the fourth capacitance.

19. A semiconductor measurement method using a semiconductor measurement device including:
a CBCM circuit having a first terminal and a connection terminal; and
a potential difference application circuit connected to the connection terminal, the potential difference application circuit having a second terminal and applying a predetermined potential difference with respect to an output of the first terminal, the method comprising:
obtaining a parasitic capacitance of a measurement system from a capacitance in a connected state in which the first terminal and the second terminal are connected to a transistor and a capacitance in a disconnected state in which the first terminal and the second terminal are disconnected from the transistor, and calculating a capacitance of the transistor.

20. The semiconductor measurement method according to claim 19,
wherein the semiconductor measurement device further includes:
a switch terminal connected to a gate terminal that is a terminal of a gate or base of the transistor in the connected state;
a gate switch that connects the switch terminal to the first terminal or the second terminal;
a ground circuit that outputs a ground potential;
a second region switch that connects a second region terminal that is a terminal of a second region of the transistor to the ground circuit and disconnects the second region terminal from the ground circuit; and
a control unit that controls the gate switch and the second region switch, and
wherein, when the capacitance of the transistor is measured,
a first capacitance is measured by causing the gate switch to connect the switch terminal to the second terminal, causing the second region switch to be disconnected, bringing the first terminal and a first region terminal that is a terminal of a first region of the transistor into the disconnected state, and bringing the gate terminal and the switch terminal into the disconnected state,
a second capacitance is measured by causing the gate switch to connect the switch terminal to the second terminal, causing the second region switch to be disconnected, bringing the first terminal and the first region terminal into the connected state, and bringing the gate terminal and the switch terminal into the connected state,
a third capacitance is measured by causing the gate switch to connect the switch terminal to the first terminal, causing the second region switch to be connected, bringing the first terminal and the first region terminal into the disconnected state, and bringing the gate terminal and the switch terminal into the disconnected state,
a fourth capacitance is measured by causing the gate switch to connect the switch terminal to the first terminal, causing the second region switch to be connected, bringing the first terminal and the first region terminal into the connected state, and bringing the gate terminal and the switch terminal into the connected state, and
the capacitance of the transistor is calculated from the first capacitance, the second capacitance, the third capacitance, and the fourth capacitance.
